(19) United States
(12) Patent Application Publication
(10) Pub. No.: US 2025/0070528 A1
(43) Pub. Date: Feb. 27, 2025

(54) STRUCTURED WAFER AND OPTOELECTRONIC COMPONENT PRODUCED THEREWITH

(71) Applicant: Schott AG, Mainz (DE)

(72) Inventors: Andreas Ortner, Gau-Algersheim (DE); Fabian Wagner, Mainz (DE); Martin Blezinger, Mainz (DE); Ulrich Peuchert, Bodenheim (DE); Tilmann Götze, Einbeck (DE)

(73) Assignee: Schott AG, Mainz (DE)

(21) Appl. No.: 18/726,213

(22) PCT Filed: Dec. 9, 2022
(86) PCT No.: PCT/EP2022/085161

§ 371 Date: Jul. 2, 2024

(30) Foreign Application Priority Data
Jan. 3, 2022 (DE) 10 2022 100 008.7

(51) Int. Cl. H01S 5/02255; H01S 5/02208; H01S 5/02218; H01S 5/02326

(52) U.S. Cl. CPC H01S 5/02255; H01S 5/02208; H01S 5/02218; H01S 5/02326

(57) ABSTRACT

The invention relates to an encapsulated optoelectronic component having a housing and at least one optoelectronic component, which is arranged in a cavity which is formed by a main element and is covered on an upper side by a cover element, and therefore the optoelectronic component is arranged between the cover element and the main elements and the main element forms side walls which laterally enclose the cavity. A one-part plate element with at least one tongue-shaped deflecting element is arranged between the cover element and the main element in such a way that, in the cavity, the deflecting element is arranged with at least one optical surface by which electromagnetic radiation emitted or received by the optoelectronic component can be deflected. The invention also relates to at least one wafer with deflecting elements, to a composite assembly of encapsulated optoelectronic components and to a method for the production thereof.

### CROSS-REFERENCE TO RELATED APPLICATIONS

This application is a national stage entry under 35 U.S.C. § 371 of International Patent Application No. PCT/EP2022/085161 entitled “STRUCTURED WAFER AND OPTOELECTRONIC COMPONENT PRODUCED THEREWITH,” filed on Dec. 9, 2022, which is incorporated in its entirety herein by reference. International Patent Application No. PCT/EP2022/085161 claims priority to German Patent Application No. 10 2022 100 008.7 filed on Jan. 3, 2022, which is incorporated in its entirety herein by reference.

### BACKGROUND OF THE INVENTION

### 1. Technical Field of the Invention

The invention relates generally to encapsulated optoelectronic components for emission or for reception of electromagnetic rays, especially light of defined wavelengths. In particular, the invention relates to encapsulated edge-emitting laser diodes.

### 2. Description of the Related Art

Optoelectronic components, for example light-emitting diodes, especially what are called Edge Emitting Laser Diodes (EELD), i.e. edge-emitting laser diodes produced on a wafer or chip basis, are generally operated in a dry, hermetically sealed housing in order to extend their lifetime. The light emitted by the diodes in these cases emerges from the housing from a lateral window, or through a window above the diode after deflection by a prism or mirror. FIGS. 1 and 2 each show one of these two designs that are known from the prior art.

The housing base material here generally consists preferably of silicon or of glass or glass-ceramic. In order to have a minimum influence on the beam quality as it leaves the housing, the passage surfaces and/or reflection surfaces are typically executed as single-or double-sidedly polished optical surfaces.

Both the manufacture of the optical components in microsystems technology, for example windows, prisms, mirrors, etc., and the assembly thereof to form a hermetically sealed housing, have more of a resemblance to the conditions of manufacture of individual parts, and are time-consuming and laborious and therefore costly.

Typically, a flat substrate with a cavity thereon or a substrate with a cavity, for example made of glass or glass-ceramic, and the windows are assembled by sealing or bonding and joined to form a hermetically sealed housing. The mounting of a prism and in particular of an edge-emitting diode at right angles to the plane of the substrate entails a large amount of labor and hence leads to high costs.

Furthermore, oblique structuring of the side walls in order to create a deflecting apparatus for the light emitted by the diode entails reduced optical properties of a finished surface, which is caused, for example, by process-related roughness or unevenness.

US 2018 287334 A1 describes, for example, a light source device comprising a base element, a semiconductor laser disposed on the base element, and a sidewall section formed such that it surrounds the semiconductor laser, and a transparent cover. The sidewall section has an inclined reflective surface such that light emitted by the semiconductor laser is reflected to the cover. The creation of such oblique walls in silicon, for example by anisotropic etching depending on the crystal orientation, especially in the case of specifically selected angles, for example an angle of 45°, is complex and associated with high costs.

### SUMMARY OF THE INVENTION

It is therefore an object of the invention to make the optical setup within a housing easily and flexibly configurable and especially also to provide and to manufacture a hermetically sealed housing, especially for optoelectronic components, for example laser diodes in a large number in parallel and as far as possible in a wafer-based manner.

Accordingly, the invention relates to a structured wafer for production of an assembly of encapsulated optoelectronic components with deflecting elements for deflection of electromagnetic rays. The wafer is in sheet form and extends in a longitudinal direction and a transverse direction and is a sheet having two opposite lateral faces, and has a multitude of openings arranged in a grid distribution and separated from one another in longitudinal and transverse direction. At least one tongue-shaped foldover region is defined in the region of each opening, where a tongue-shaped deflecting element with at least one optical surface can be formed in each case by folding over the foldover region and is permanently reversibly deformable as part of the one-piece structured wafer in such a way that each deflecting element can be repeatedly inclined or bent about at least one first axis.

By means of the repeatedly tiltable deflecting element, the optical surface of the deflecting element can advantageously be set at any angle within an encapsulated optoelectronic component, for example between 0° and 90°. In this way, the light beam emanating from the diode can be adjusted as desired.

The optical surface of at least one deflecting element is preferably planar, in particular such that the light beam emanating from the diode or the light beam coming from a wall or a cover element is deflected uniformly. With a planar surface, better steering of light, for example reflection, is possible.

What is meant by “tongue-shaped” in the context of the invention is that at least a section of the tongue-shaped foldover region and/or of the tongue-shaped deflecting element is joined to the wafer. Another section preferably projects into the opening. The tongue-shaped foldover region and/or the tongue-shaped deflecting element may be in elongated form and be joined to the wafer on a narrow side. On the other hand, it is alternatively possible that a long side is joined to the wafer.

It is equally possible for the tongue-shaped foldover region and/or the tongue-shaped deflecting element to have a rectangular or square shape. However, other shapes are likewise conceivable, for example oval, round, semicircular, trapezoidal or triangular shapes, or generally freeform areas, in which one section in each case is bonded to the wafer. In general, the tongue-shaped foldover region or the tongue-shaped deflecting element may extend in a longitudinal direction and a transverse direction. The long side here may be longer than the transverse side, or the transverse side may be longer than the long side.

In order to simplify the production of encapsulated optoelectronic components and to make it less expensive, many individual components are usually first produced in an assembly, and these are singularized later. In one advantageous embodiment, it is therefore the case that the openings are arranged in such a way that, by removing sections of the wafer along dividing lines between the openings, singularized one-piece sheet elements each having an opening with a frame and at least one deflecting element bonded to the frame are obtainable.

The object can therefore also be achieved by an assembly of encapsulated optoelectronic components, whereby the assembly forms a housing with at least one base element and a cover element, wherein a multitude of optoelectronic components are respectively disposed in one cavity of the housing which is formed by the base element and is covered on a top side by the cover element, such that the optoelectronic components are disposed between the cover element and the base element, and the base element forms side walls that each laterally enclose a cavity, where the base element especially comprises a substrate with recesses that define the cavities and/or define a carrier and a spacer disposed thereon and having openings that define the cavities, wherein a one-piece structured wafer with tongue-shaped deflecting elements is disposed between the cover element and the base element and/or between the carrier and substrate, wherein a tongue-shaped deflecting element having at least one optical surface which is bent or repeatedly tiltable or bendable about at least one first axis is disposed in each cavity, with which electromagnetic radiation which is emitted or received by the optoelectronic components is deflectable.

It is advantageous when the base element, especially the substrate, likewise takes the form of a wafer. It is equally also possible for the carrier and/or the spacer to take the form of a wafer. In a further embodiment, the cover element may also take the form of a wafer. If at least one of these elements, or preferably a multitude or all of these elements, take(s) the form of a wafer, these elements can be stacked one on top of another and/or aligned to one another in a particularly simple manner, such that the assembly of encapsulated optoelectronic components is producible in a particularly simple manner. The assembly therefore preferably has at least four wafers, especially a cover wafer, a wafer with deflecting elements, a carrier wafer and a spacer wafer.

The assembly therefore has at least one, preferably more than one, of the following features:
the wafer, especially the structured wafer and/or at least one deflecting element, has a thickness in the range of 0.03 mm to 1.3 mm, preferably in the range of 0.05 mm to 0.4 mm,
the spacer has a thickness in the range of 0.3 mm to 3.0 mm, preferably in the range of 0.7 mm to 2.6 mm, more preferably in the range of 0.7 mm to 1.5 mm,
the carrier has a thickness in the range of 0.3 mm to 3.0 mm,
the cover element has a thickness in the range of 0.1 mm to 2.0 mm, preferably in the range of 0.2 mm to 1.2 mm auf, more preferably in the range of 0.3 mm to 0.8 mm.

In this way, for example, the spacer provides a cavity having sufficient height which is particularly suitable for the accommodation of diodes, especially edge-emitting diodes. The cover element is preferably thinner than the spacer and/or the carrier. The wafer, or structured wafer, ideally takes the form of a thin glass wafer and/or is thinner than the cover element and/or the carrier, in order to provide the movable deflecting element, or the movable deflecting elements.

Further embodiments envisage at least one of the following features:
the wafer comprises or consists of glass, glass-ceramic, ceramic, metal, plastic, or a mixture or combination of these materials,
the carrier or the substrate comprises or consists of glass, glass-ceramic and/or ceramic,
the base element or the spacer comprises or consists of glass, glass-ceramic and/or ceramic,
the cover element comprises or consists of glass, especially glass at least partly transparent to electromagnetic rays,
the cover element comprises or consists of tempered and/or toughened glass.

When the carrier or else the substrate is made from glass, glass-ceramic and/or ceramic, in a particularly preferred embodiment, it may also take the form of a submount and/or of an electronic, especially multilayer, printed circuit board, especially such that optoelectronic components can be positioned on the carrier, or on the substrate. In a further embodiment, the submount surface is also joined to a heatsink by a thermally conductive epoxy layer. In the best case, the optoelectronic components are then also connectable to an (electrical) circuit via the carrier or substrate.

In order to allow electromagnetic radiation out of the housing, or admit it into the housing, at least the cover element and/or the spacer, or the substrate, comprises a material at least partly transmissive to electromagnetic radiation in one or more wavelength ranges, especially glass. In order to achieve lateral emission, the spacer, or the substrate, preferably includes a material at least partly transmissive to electromagnetic radiation. In the case of an encapsulated optoelectronic component that emits upward, the cover element preferably includes a material at least partly transmissive to electromagnetic radiation. Such a material is preferably also used in an embodiment in which an electromagnetic ray is incident from above on the encapsulated optoelectronic component, or the cover element.

Such an assembly of encapsulated optoelectronic components can be used in a simple manner for production of individual encapsulated optoelectronic components.

The object may therefore also be achieved by an encapsulated optoelectronic component, especially an encapsulated optoelectronic component producible or produced from the assembly described above. The encapsulated optoelectronic component has a housing and at least one optoelectronic component disposed in a cavity which is formed by a base element and is covered on a top side by a cover element, such that the optoelectronic component is disposed between the cover element and the base element. The base element forms side walls that laterally enclose the cavity, where the base element comprises a substrate having at least one recess that defines the cavity and/or a carrier and a spacer disposed thereon and having at least one opening that defines the cavity. A one-piece sheet element having at least one bent tongue-shaped deflecting element is disposed between the cover element and the base element in such a way that there is disposed, in the cavity, the deflecting element with at least one optical surface by which electromagnetic radiation which is emitted or received by the optoelectronic component is deflectable.

Since the encapsulated optoelectronic component is especially produced inexpensively on a wafer basis, or by singularization from an assembly, it may be the case that the encapsulated optoelectronic component is rectangular or square in shape. The side lengths of such a component may then, for example, be between 3 mm and 12 mm, preferably between 5 mm and 7 mm. Particular preference is given to square dimensions of 7×7 mm, or rectangular dimensions of 5×10 mm. Such dimensions are of particularly good suitability for microelectronics applications and are compatible with other components in this field of application. It is alternatively possible to implement different measures with a side length of more than 12 mm and/or less than 3 mm. It is likewise possible for the optoelectronic components to have other shapes as well, for example oval, round, circular, trapezoidal or triangular shapes, especially shapes in which the sidewalls are at an oblique angle to one another, for example, as in a parallelogram.

In a particular embodiment, at least one actuator, preferably two or more actuators, is/are arranged such that the deflecting element is alignable by the actuator, or the actuators, especially such that the beam path of the light emitted by the light source/diode is reversibly variable or controllable during operation with the aid of the actuator(s) via alignment of the deflecting element.

In a further embodiment, the deflecting element is deformed and/or deformable, especially such that the deflecting element has a concave or convex shape. It is conceivable, for example, that the deflecting element is designed as a mirror adapted to a wavefront, preferably as a mirror adapted to a wavefront of electromagnetic radiation, especially a range of predetermined wavelengths.

The object is especially also achieved by a method of producing an encapsulated optoelectronic component, especially for production of an above-described encapsulated optoelectronic component, in which:
cuts are created in at least one of the lateral faces of a sheetlike wafer, wherein
cuts are created in the wafer along several defined and mutually spaced-apart closed paths and
cuts in the wafer are created along several defined and mutually spaced-apart connecting paths and
wherein the cuts of the closed paths run through the wafer, from one lateral face to an opposite lateral face, and
the cuts of the closed paths create a material-weakened structure such that a sector is generated adjoining each connecting path that forms a tongue-shaped foldover region that remains at least indirectly connected to the wafer, wherein
a multitude of optoelectronic components, a base element having cavities, the wafer and at least one cover element are provided, and
one optoelectronic component is disposed in each cavity and the wafer is disposed between the cover element and the base element such that an assembly of encapsulated optoelectronic components, especially an assembly as described above, is produced, wherein
at least one foldover region is tilted such that at least one deflecting element or all deflecting elements is/are tilted into a cavity, wherein
the assembly, especially the wafer assembly, of encapsulated optoelectronic components is singularized along dividing lines between the cavities to give individual encapsulated optoelectronic components, especially to give above-described encapsulated optoelectronic components.

Such a folded-under deflecting element serves as a deflecting optical surface, especially as a mirror surface, the optical properties of which are determined by, for example, the reflection properties of the wafer (refractive index, reflectance), the surface quality thereof (waviness, roughness) and the properties of any coating applied.

In order to assure the quality of the emitted laser beam from the optoelectronic components on reflection at a folded-out mirror or deflecting element, or transmittance through glass surfaces or a folded-out mirror, via uniform optical properties, direct contact of optical surfaces should be avoided. Therefore, in a further embodiment, a further spacer is disposed between the structured wafer and the cover that prevents direct contact of the surfaces.

In an advantageous embodiment, it is envisaged that at least the cuts in the wafer be generated by laser, especially an ultrashort-pulse laser. Preference is given to using a method of laser material processing, especially laser filamentation, in order to precisely determine and monitor the penetration depth of the cuts, or of the filaments.

### BRIEF DESCRIPTION OF THE DRAWINGS

The invention is elucidated more specifically hereinafter with reference to the appended figures. In the figures, identical reference numerals each refer to identical or corresponding elements. The figures show:

FIG. 1 a design of an encapsulated laser diode known from the prior art;

FIG. 2 a design of an encapsulated laser diode known from the prior art;

FIG. 3 a schematic diagram of the creation of damage in the wafer by a laser;

FIG. 4 a schematic diagram of a glass element with multiple damage sites;

FIG. 5 a schematic progression of the cutting pathways for production of a wafer with deflecting elements;

FIG. 6 a schematic diagram of a wafer with deflecting elements in top view;

FIGS. 7-10 a schematic top view of various embodiments of the material-weakened structure;

FIGS. 11-13 a schematic cross section of various embodiments of the material-weakened structure;

FIG. 14 a schematic diagram of the singularization of an assembly of encapsulated optoelectronic components;

FIG. 15 a schematic diagram of the wall of the spacer;

FIG. 16 a schematic diagram of the construction of an encapsulated optoelectronic component with its component parts;

FIG. 17 an encapsulated optoelectronic component with a cover element with a projection;

FIG. 18 a schematic diagram of the production of an oblique edge on the deflecting element;

FIG. 19 an encapsulated optoelectronic component with an oblique edge on the spacer;

FIGS. 20-22 various alignments of the deflecting element;

FIG. 23 a schematic diagram of a deflecting element with a deflecting section and a positioning section;

FIG. 24 a schematic diagram of a deflecting element with two deflecting sections;

FIGS. 25-28 various geometric designs of the deflecting element;

FIG. 29 an assembly with two structured wafers, the deflecting elements of which are angled with respect to one another, such that positioning and alignment of the laser beam in two independent directions is possible.

### DETAILED DESCRIPTION OF THE INVENTION

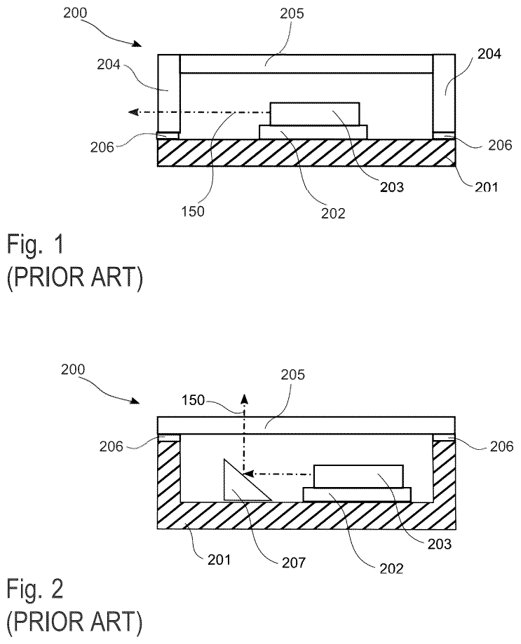

FIGS. 1 and 2 each show a design 200 from the prior art. FIG. 1, for example, shows a design 200 of an encapsulated laser diode chip 203. The laser diode chip 203 is disposed on a submount 202, which is in turn mounted on a ceramic substrate. A cavity is produced in that the cap 205 has lateral windows 204 between which the cavity is formed. The cap 205 is connected to the window 204 by means of an adhesive 206 such that the capsule is hermetically sealed. The laser diode chip 203 emits the light along the ceramic substrate 201, such that the light beam 150 exits laterally through the window 204.

FIG. 2 shows another design 200 from the prior art in which the light beam 150 is emitted not laterally but at a fixed defined angle upward through the cap 205. The light beam 150 emitted by the laser diode chip 203 is deflected upward here at a fixed angle through a mirror prism 207 disposed on the ceramic substrate 201. In this design, the cavity is formed by a hollow ceramic substrate 201.

The disadvantage of the designs 200 shown in FIGS. 1 and 2 is that the emission angle of the light beam 150 is not choosable flexibly, and is especially not choosable individually and in particular cannot be altered subsequently, i.e. after the mounting of the encapsulated laser diode. In particular, the mounting of individual deflecting elements, for instance in the form of small prisms in the wafer assembly, is also very complex.

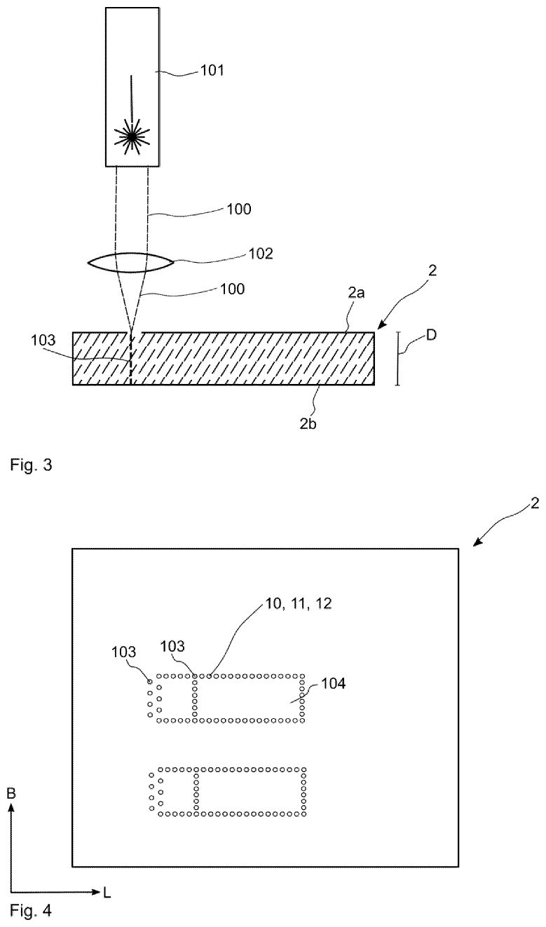

FIGS. 3 to 16 therefore show a process for producing an encapsulated optoelectronic component 1, especially with a tongue-shaped foldover region, wherein a tongue-shaped deflecting element with at least one optical surface 30 can be formed by folding over the foldover region 13. The deflecting element 14 here is repeatedly tiltable or bendable about at least one first axis, but it is possible in particular to alter the angle of the deflecting element 14, or the position thereof, if appropriate, even after the mounting of the encapsulated laser diode.

In a first step, a sheetlike wafer 2, especially made of glass or glass-ceramic, is first provided. More preferably, the wafer 2 is a thin glass wafer. The wafer 2 has a thickness D of greater than 0.03 mm, preferably greater than 0.05 mm, more preferably greater than 0.1 mm, and/or less than 1.3 mm, preferably less than 0.4 mm. Such thicknesses are of particularly good suitability for use as an additional element in an encapsulated optoelectronic component 1.

In an advantageous embodiment, the wafer 2 may comprise or consist of borosilicate glass. However, it is also possible to use one of the following chemical compositions, where the following compositions are reported in % by weight:

| | |
|---|---|
| SiO₂ | 58 to 65 |
| B₂O₃ | 6 to 10.5 |
| Al₂O₃ | 14 to 25 |
| MgO | 0 to 3 |
| CaO | 0 to 9 |
| BaO | 3 to 8 |
| ZnO | 0 to 2, |

where the sum total of the content of MgO, CaO and BaO is in the range of 8% to 18% by weight.

The composition of the wafer 2 is given by way of example by the following composition:

| | |
|---|---|
| SiO₂ | 30 to 85 |
| B₂O₃ | 3 to 20 |
| Al₂O₃ | 0 to 15 |
| Na₂O | 3 to 15 |
| K₂O | 3 to 15 |
| ZnO | 0 to 12 |
| TiO₂ | 0.5 to 10 |
| CaO | 0 to 0.1 |

The composition of the wafer 2 may also be given by way of example by the following composition:

| | |
|---|---|
| SiO₂ | 40 to 50 |
| B₂O₃ | 10 to 20 |
| Al₂O₃ | 10 to 20 |
| As₂O₃ | less than 1 |
| BaO | 20 to 30 |
| CaO | less than 1 |

The composition of the wafer 2 may also be given by way of example by the following composition:

| | |
|---|---|
| SiO₂ | 70 to 82 |
| B₂O₃ | 10 to 20 |
| Al₂O₃ | 1 to 10 |
| Na₂O | 1 to 10 |
| K₂O | less than 1 |
| Fe oxide | less than 1 |
| Cl oxide | less than 1 |

Such compositions can be processed, or structured, particularly efficiently by a laser method. In addition, these types of glass are also of particularly good suitability for enabling bending for the deflecting element without any great risk of fracture. The composition of the glass, or of the wafer, is preferably selected such that the coefficient of thermal expansion thereof is matched to the thermal properties of the carrier, the cover element and/or the spacer. In this way, it is possible to avoid or at least reduce stresses between the components, especially in the case of heating during the operation of the optoelectronic component.

As shown by way of example in FIG. 3, the wafer 2 may be structured in a further step as follows by means of an ultrashort pulse laser or laser ablation:
a laser beam 100 from an ultrashort pulse laser 101 is directed onto one of the lateral faces 2a of the sheetlike wafer 2 and is preferably concentrated into the wafer material by focusing optics 102, especially to an elongated focus. The incident energy from the laser beam 100 creates filamentous damage 103 in the volume of the wafer 2, the length of which runs transverse to a lateral face 2a, 2b of the wafer 2, especially at right angles to the lateral face 2a, 2b, and, in order to generate filamentous damage 103, the ultrashort pulse laser 101 emits a pulse or a pulse packet comprising at least two successive laser pulses.
The point of incidence of the laser beam 100 on the wafer 2 is run along multiple defined and spaced-apart paths 10, 11, 12, such that
a multitude of juxtaposed filamentous damage sites 103 have been introduced along the paths.

Through choice of suitable laser parameters, it is possible to influence or even adjust the dimensions and distances between the damage sites 103. A suitable laser source according to the present invention may be a neodymium-doped yttrium aluminum garnet laser (Nd: YAG laser) having a wavelength of 1064 nanometers. The laser source generates, for example, a raw beam having a (1/e²) diameter of 12 mm. The optics used may comprise a biconvex lens having a focal length of 16 mm. The raw beam may optionally be generated using suitable beamforming optics, for example a Galilei telescope. The laser source preferably works at a repetition rate of between 1 kHz and 1000 kHz, preferably between 2 kHz and 100 kHz, more preferably between 3 kHz and 200 kHz. This repetition rate and/or the scan rate may be chosen such that a desired distance between adjacent damage sites is attained.

Other variants of the Nd: YAG laser, such as the wavelengths of 532 nm or 355 nm produced by frequency doubling (SHG) or frequency tripling (THG), or else such as the Yb: YAG laser (emission wavelength 1030 nm), may likewise be used as radiation sources in a suitable manner.

It is also conceivable that a laser pulse is divided into a multitude of individual pulses, and the multitude is less than 10, preferably less than 8, preferably less than 7, and/or greater than 1, preferably greater than 2, preferably greater than 3. These individual pulses may be combined to form a pulse packet, called a burst, and are especially emitted in successive laser pulses. These individual pulses are preferably directed to the same place or the same site on the lateral face 2a, 2b, such that the damage sites 103 are widened ever further by the successive individual pulses, especially such that channels are formed that run, for example, across the whole thickness D or the volume of the wafer 2.

FIG. 4 shows, by way of example and without restriction to the example shown, an arrangement of filamentous damage sites 103 that have been generated in the wafer 2. The wafer extends here in a longitudinal direction L and a transverse direction B. The paths 10, 11, 12 accordingly lie in longitudinal direction L and in transverse direction B. In this way, the total area of the wafer 2 may be divided, in a preferably regular arrangement, into subareas 104 that can each offer suitable openings for optical components. Such openings may be generated in a later process step.

In one embodiment, a multitude of damage sites 103 is generated in the wafer 2 in order, ideally, to be able to form a perforation of the wafer 2 by means of the damage sites 103, especially around subareas 104. For this purpose, it is preferable to generate multiple damage sites 103 alongside one another such that a row of damage sites 103 constitutes a larger structure which is preferably defined by the paths 10, 11, 12. The damage sites 103 especially take the form of filamentous channels, the longitudinal direction of which runs transverse to at least one lateral face 2a, 2b of the wafer 2.

These channels extend at least from a lateral face 2a, and especially at right angles from this lateral face 2a, into the wafer 2 and break through at least that lateral face 2a. However, the channels preferably extend from one lateral face 2a to the opposite lateral face 2b, as shown for example in FIG. 1.

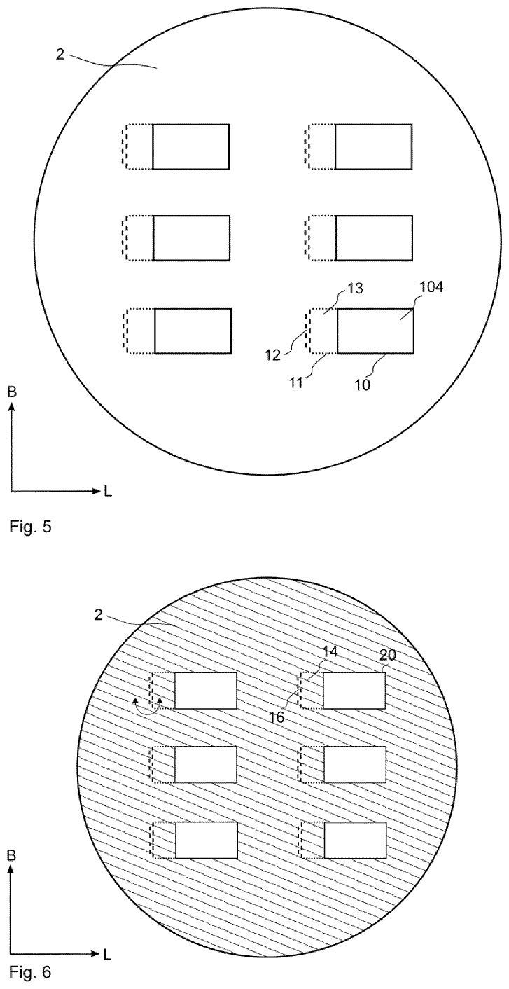

Without restriction to the example shown, FIG. 5 shows, by way of example, different paths 10, 11, 12. Accordingly, damage sites 103 may be generated along closed paths 10, open paths 11 and connecting paths 12. The respective paths 10, 11, 12 preferably define different structures, such that, for example, the closed paths 10 enclose the envisaged subareas 104, each of which can offer openings 20 for optical components. Open paths 11 can preferably run, or be generated, adjacent to closed paths 10. The open paths 11 especially adjoin a closed path 10 by one end, and a connecting path 12 by the other end. It is possible here for the open paths 11 to be formed as an extension of subsections of the closed paths 10.

In addition, it is also possible to define tongue-shaped foldover regions 13 between open paths 11 and connecting paths 12. It is preferable here that there is a tongue-shaped foldover region 13 on each subarea 104, where the subarea 104 may be separated from the foldover region 13 by at least one open path 11 and/or at least one closed path 10. However, the foldover region may also at least partly be surrounded by a closed path 10, and may especially adjoin a connecting path 12 on an opposite side from the closed path 10. This is the case, for example, when the foldover region 13 is in semicircular or semioval form. The connecting path 12 in this case lies between two corners of the closed path 10.

It is conceivable that the closed 10 and/or open paths 11 are interrupted by at least one, preferably more than one, severable subregion, especially in such a way that each foldover region 13 remains connected to the wafer 2 via the subregions during further process steps.

The best arrangement of the foldover region 13 is such that it can be folded over after an etching operation, where it remains at least indirectly or directly connected to the wafer 2. Indirect connection here means connection via the material-weakened structure. A deflecting element 14 is preferably formed in each case by folding over a foldover region 13. Accordingly, the deflecting element 14 may have a shape corresponding to the foldover region 13, and vice versa.

The closed paths 10, the open paths 11 and/or the connecting paths preferably have a linear progression, especially in the longitudinal direction L and/or the transverse direction B of the wafer 2. It is possible here for the subareas 104, or openings, to have a rectangular or square shape. The paths 10, 11, 12 may alternatively be bent, or curved, for example semicircular, especially such that the foldover region 13, or the deflecting element 14, has at least one rounded edge or corner.

In one embodiment, the wafer, after the insertion of the filamentous damage sites 103, is exposed to an etch medium 300, especially along the paths 10, 11, 12, wherein
the etching increases the diameter of the channels to such an extent that the wafer material is removed between the channels of the closed paths 10 and open paths 11 and the channels are combined, such that a multitude of mutually separate openings 20 in a grid distribution and tongue-shaped foldover regions 13 disposed thereon are formed in the wafer 2, and
the etching increases the diameter of the channels to such an extent that the wafer material is removed between the channels of the connecting paths 12 in such a way that, in the region of each connecting path 12, a material-weakened structure 16 is formed and the foldover region 13 between the open paths 11 or an open path 11 and a closed path 10 forms a deflecting element 14 that remains connected to the wafer 2 via the material-weakened structure 16.

In an alternative embodiment, the subareas 104 of the wafer 2 may preferably be structured in the form of relatively small rectangular regions, especially in such a way that a perforation of the material is conducted on 3 sides of the rectangle. In other words, introduction of the damage sites 103 creates a perforation of the material along the closed 10 and/or open paths 11, for example by means of a laser, or laser filamentation. The subareas 104, or the foldover regions 13, may then be opened by introducing mechanical stress, preferably by a fracturing process. On the fourth side of the rectangle, especially at the connecting path 12, the material, however, is structured in such a way that the material can be permanently and reversibly deformed, preferably in such a way that this region serves as a hinge for bending or folding of an inner rectangle or differently shaped foldover region 13.

Accordingly, cuts in the context of the invention can be defined as closed paths 10, open paths 11 and/or connecting paths 12 that have been modified, for example widened or broken up, in the course of an etching process or a mechanical process. The paths 10, 11, 12 may alternatively be regarded as cuts, especially since the cuts run analogously to the paths 10, 11, 12.

FIG. 6 therefore shows, by way of example, a structured wafer 2 with mutually spaced-apart openings 20. A foldover region 13 is disposed at each opening 20, and this can be folded over to give a deflecting element 14, for example, by exerting a mechanical force. This deflecting element 14, or the foldover region 13, is bonded to the wafer 2 via the material-weakened structure 16 that preferably runs analogously to a connecting path 12.

It is advantageous, therefore, when each deflecting element 14 is bonded to the wafer 2 by a section with a material-weakening structure 16, such that smaller deformation forces are required for bending of the wafer material in this section than in an unstructured section. In this way, the deflecting element 14 can be bent repeatedly, especially as often as desired, or preferably folded or tilted. It is possible here ideally to freely choose the angle of inclination, for example within a range between 90° and 0°, such that light can be deflected accordingly in accordance with the envisaged use.

In a further embodiment, each deflecting element 14 is joined to the wafer 2 by at least one, preferably more than one, severable subregion, such that the deflecting element 14 remains joined to the wafer 2 after the subregion has been severed, especially merely via the material-weakening structure 16. In this way, handling and transport of the wafer 2 can be facilitated, especially if the glass processing and the assembly of the diode, or joining of individual elements to give the optoelectronic component 1, take place separately. The deflecting elements 14 in this case would be fixed during transport and would not be able to tip over in an uncontrolled manner.

At least one of the following features is also conceivable:
the material-weakening structure 16 has recesses 90 that run across the thickness D of the wafer 2 at least partly through the wafer material, such that only one lateral face 2a is broken through by the recesses 90,
the material-weakening structure 16 has recesses that run across the thickness D of the wafer 2 completely through the wafer material, such that two opposite lateral faces 2a, 2b are broken through by the recesses,
the material-weakening structure 16 has recesses 90 that are arranged alongside one another such that the regions between which the material-weakening structure is disposed are connected to one another by lands 92, 94,
the recesses 90 are elongated, where the longitudinal direction thereof preferably runs parallel to an axis of inclination or bending of the deflecting element 14, especially to the first axis 31,
the recesses 90 are arranged in rows in the direction of the axis of inclination or bending,
the recesses are arranged in rows in the direction of the axis of inclination or bending, where the recesses 90 arranged in rows are offset from one another.

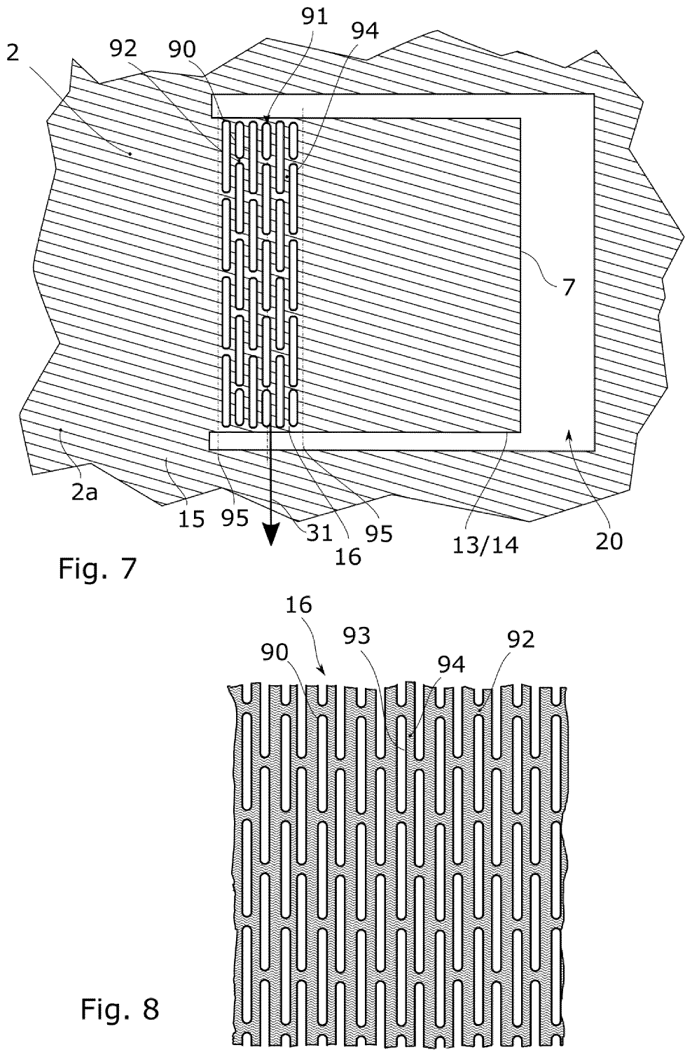

FIG. 7 shows one embodiment of the material-weakening structure 16. The wafer 2 is shown as a detail in top view of one of the lateral faces 2a thereof. The surface of the wafer is shown here as a hatched area. The wafer 2 preferably consists of glass, especially thin glass. The wafer 2 can be divided into three sections in this detail, namely a first section in the form of a material-weakened structure 16 with recesses 90 and a second section 15 adjoining the material-weakened structure 16, and a foldover region 13, or the deflecting element 14. The second section is the region of the wafer 2 that surrounds the deflecting element 14 and at which the deflecting element 14 is secured at least indirectly via the material-weakened structure 16. The material-weakened structure 16 lies between the second section 15 and the deflecting element 14. The second section 15 and the deflecting element 14, or the foldover region 13, preferably have a continuous flat surface and hence in particular no recesses 90. By contrast, the recesses 90 in the material-weakened structure 16 in one embodiment form passages or passage holes from one lateral face 2a to the opposite nonvisible lateral face 2b.

On the other hand, it is also conceivable or possible to execute the connection of the foldover element to the wafer without material-weakening structure. The foldover element may then likewise be brought into position by bending the glass. Such an embodiment is particularly suitable for very thin glasses having thicknesses of less than 50 μm, preferably not more than 30 μm.

Without restriction to the specific example shown in FIG. 7, the recesses 90 are generally arranged in an arrangement of adjacent parallel lines 91. These lines may run, for example, parallel to a first 31 or second axis 32 at which the deflecting element 14 can be folded over or tilted. The rows of recesses 91 are preferably arranged in parallel. In this way, the distance between the recesses 90 of adjacent rows 91 remains constant. The recesses 90 within a row 91 are separated by first lands 92. In addition, the openings 90 of adjacent rows 91 are separated by second lands 94. Thus, the material-weakened structure 16 may generally also be described as a network of mutually bonded first and second lands 92, 94 with intervening recesses 90.

By virtue of the mesh of recesses 90 and lands 92, 94, the material-weakened structure 16 has high flexibility, such that the wafer 2 of the material-weakened structure 16 can be bent easily. Flexibility is particularly high when elongated recesses 90 are introduced into the wafer 2 in order to form the material-weakened structure 16. In particular, it is advantageous when the longitudinal direction of the recesses 90 runs in the longitudinal direction of the rows 91. By the shape of the lands 92, 94 and the respective dimensions thereof, it is possible to influence and reduce bending forces. In general, without restriction to the working example shown, the arrangement and shape of the lands 92, 94 is designed such that the flexibility of the material-weakened structure 16 at the first axis 31, especially a bending axis in the longitudinal direction of the recesses 90, is higher than at a bending axis at right angles to the longitudinal direction of the recesses 90. The preferred bending axis, especially the first axis 31 in the direction of the longitudinal direction of the recesses 91, is shown in FIG. 7. Since the bending axis extends along the boundary lines 95 between the second section 15 and the foldover region 13, or the deflecting element 14, the material-weakened structure 16 provides a hinge in order to fold the deflecting element 14 preferably as often as desired and/or to tilt it at a desired angle.

Moreover, as apparent from FIG. 7, the first lands 92 of adjacent rows 91 are offset from one another. The first lands also define the suspension points for the second lands 94. The offset arrangement of these suspension points results in absorption of bending of the first section 9 partly by torsion of the second lands 94. The very advantageous effect of the translation of bending stress to torsion stress is that the maximum tensile force that occurs in brittle material is reduced compared to the tensile stress that occurs in a bent, more solid sheet. Thus, the element made from brittle material may, as a general concept, also be characterized by a mesh of lands 92, 94 that are joined to one another such that bending of the deflecting element 14 leads to torsion of at least some of the lands 92, 94.

In the illustrative embodiment shown in FIG. 7, the number of second lands 94 that undergo extension by torsion is about half the total number of lands 92, 94. In a preferred embodiment, in general, it is preferable that the lands, especially the first and second lands 92, 94, form a mesh, where the lands are joined to one another such that at least a portion of the lands within the mesh undergo torsion stress on bending 2 of the material-weakened structure 16, where the portion is at least one third of the total number of lands within the mesh.

As well as bending of the deflecting element 14, it is also possible to exert stresses by means of a monoaxial tensile force along the material-weakened structure 16. In this case, the lands absorb the tensile force by bending within a plane parallel to the lateral faces 2a, 2b. Because of this bending, the accompanying stresses at the ends of the recesses 90 may converge. As in the embodiment of FIG. 7, it is generally preferred for that reason to provide recesses 90 with a rounded outline, especially an outline with rounded ends. These ends are especially in opposite positions in the direction along the rows 91. A rounded outline does not mean that the recesses 90 may also have linear sections. In fact, the embodiment of FIG. 7 has linear segments 93 of the outline that extend in the longitudinal direction of the elongated recesses 90. A rounded outline instead means that the outline of the recesses 90 does not have any sharp edges.

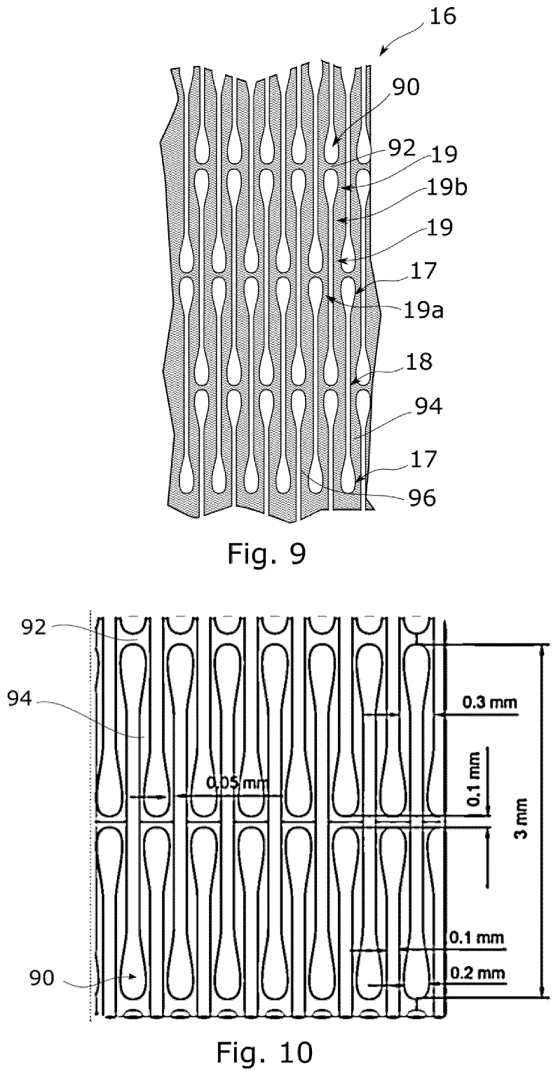

FIGS. 8 and 9 show two embodiments of the mesh of recesses 90 within the material-weakened structure 16. The embodiment of 8 is similar to that shown in 7. Accordingly, the recesses 90 are elongated and have a rounded outline with straight longitudinal edges. However, the shape of the recesses 90 and of the lands 92, 94 in the embodiment from FIG. 9 is more complex. In general, without restriction to the specific embodiment shown, the recesses 90 have a varying width in their longitudinal direction. To wit, the recesses 90 have two maxima 17 of width that are spaced apart in a longitudinal direction, with an intervening minimum 18 of width between the two maxima 17.

In a similar manner, the two lands 94 have two minima 19 of width. These minima 19a are spaced apart in the longitudinal direction of the lands 94. In addition, there is a middle maximum 19b of width between the minima 19 of width of the second lands 94.

Although the outline of the recesses 90 is more complex compared to the example of FIG. 8, the outline of the recesses 90 or of the second lands 94 in both examples has at least one linear segment 96. In particular, and in a further embodiment, the position of the intermediate maximum 19b of width in the second land 94 is in the linear section 96. The position of the intermediate minimum 18 of recess width is likewise along the linear segment 96. When opposite linear segments 96 are in a parallel arrangement, these features lead to minima and maxima extended in a longitudinal direction, i.e. in particular in the directions of the lines 91. This is advantageous in order to broaden and hence to reduce the maximum tensile stress that can occur on bending of the material-weakened structure 16 along the outline.

There follows a detailed elucidation of the effect of different dimensions of the recesses 90 and lands 92, 94 on the main stresses. For this purpose, the features of a base design and some variations thereof were examined with the aid of finite element analysis. FIG. 10 shows the material-weakened structure 16 of the base construction with the respective dimensions. For instance, the first lands 92 have a length of 0.1 mm, the second lands 94 a minimum width of 0.05 mm. The recesses 90 have a length of 3 mm and a width that varies between 0.1 mm and 0.2 mm. The thickness of the reference element 1 is 100 μm.

In a first analysis, different lengths of the first lands 92 are examined. The lengths are 50 μm, 100 μm (reference), 200 μm, and 300 μm. Finite element analysis shows that the S11 component of strain for a bending radius at 50 MPa remains virtually constant. However, the S22 component is subject to a distinct decrease with increasing length of the first lands 92. 50 MPa for land length 300 μm at a bending radius of 3 mm. Thus, in one embodiment, the length of the first lands 92 is at least as high as the wafer thickness D, preferably at least twice as high, in order to lower the overall flexural stress.

In a second analysis, different lengths of the recesses 90 are examined. Specifically, recesses having lengths of 2 mm and 3 mm were compared. The analysis shows that the length of the recesses 90 does not have any great influence on the main stresses. Thus, the recesses 90, in a further embodiment, preferably have a length at least 25 times greater than the thickness D of the wafer 2. However, if the length is too great, there is a decrease in stability against a pressure on one of the lateral faces 2a, 2b. It is therefore preferable to limit the length of the recesses 90 to not more than 100 times the wafer thickness.

In a third analysis, the minimum width of the second lands 94 is varied. Specifically, as well as the reference model with a minimum width of 50 μm, further widths of 25 μm, 35 μm and 70 μm were examined. While a reduction in the minimal land thickness has a minor effect on the S11 component, there is a distinct decrease in the S22 component. On the other hand, however, a small land width leads to a very sensitive, fracture-sensitive structure. Therefore, in a further embodiment, the minimum width of the second lands 92 is preferably less than the thickness D of the wafer 2 and is more preferably in the range from 0.3 times to 0.6 times the thickness D of the wafer 2.

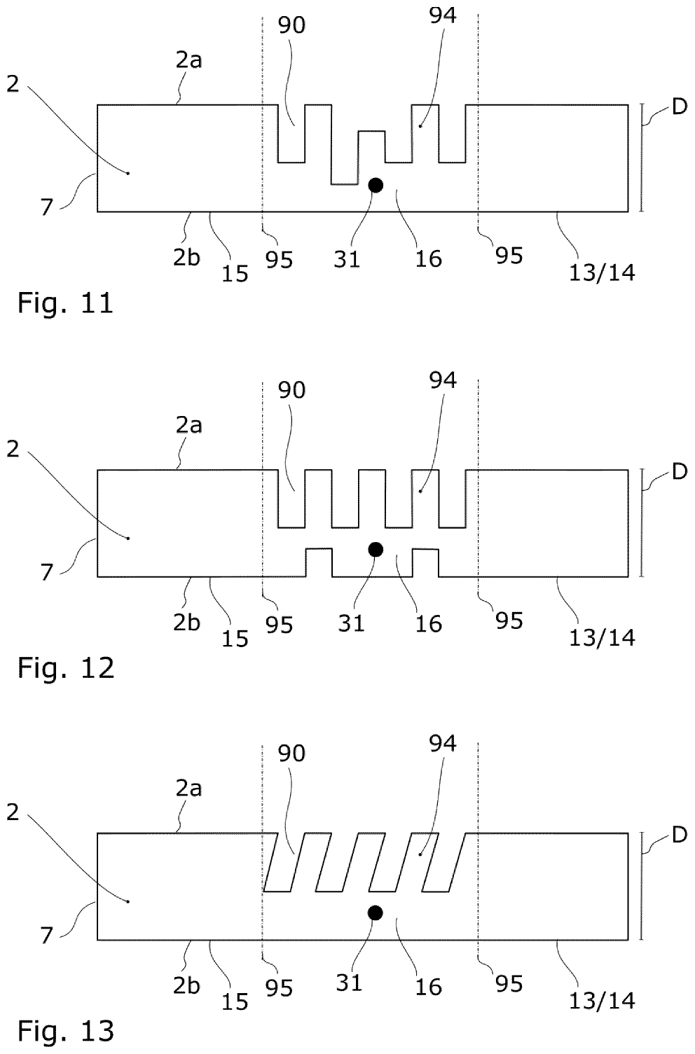

FIGS. 11 to 13 show further embodiments of the material-weakening structure 16. FIG. 11 shows, for example, a wafer 2 in a cross-sectional view across its thickness D. In the embodiment shown by way of example, the recesses 90 run along the thickness D of the wafer 2 only partly through the wafer material, such that only one lateral face 2a is broken through by the recesses 90. The cuts accordingly likewise run across the thickness D only partly through the wafer material. The cuts, i.e. the recesses 90 as well, can therefore project into the wafer material to different depths. It is possible here for the lands, especially the first 92 and/or second lands 94, to be formed with analogous height based on the thickness D. However, it is also conceivable that the lands have a different height. For example, the first lands 92 may be lower or higher than the second lands 94. The height of the lands is preferably flush with at least one of the lateral faces 2a, 2b of the wafer, especially such that an upper edge of the lands and the lateral face 2a, 2b are in one plane.

In a further embodiment, in accordance with the example of FIG. 12, recesses 90 may be disposed on both lateral faces 2a, 2b of the wafer. In this case, the recesses 90 across the thickness D of the wafer 2 likewise run only partly through the wafer material. However, the two lateral faces 2a and 2b are broken through by recesses 90, especially such that two opposite lateral faces in each case are broken through by recesses. In this way, the stresses that arise during the bending process may be more readily degraded via the elevated flexibility of the remaining residual material, or do not even arise. The opposing recesses 90 are preferably arranged offset from one another, especially such that, for example, a recess 90 in the lateral face 2b is positioned between two recesses disposed on the opposite lateral face 2a. The recesses 90 may alternatively be arranged under one another or opposite one another with regard to their respective lateral face 2a, 2b.

In a further embodiment, in accordance with the example of FIG. 13, the or at least some of the recesses 90 may be cut into the wafer at an oblique angle, especially an angle other than 90°. In this way, the material-weakening structure 16 can be matched to the desired bending direction. Such oblique recesses 90 may of course also be combined with other embodiments, for example those from FIGS. 11 and 12. It would be conceivable, for example, for the recesses 90 on one lateral face 2a of the wafer 2 to run into the wafer 2 transversely, especially at right angles, and for recesses 90 on the opposite lateral face 2b to run obliquely into the material. In this way, for example, the bending angle may be limited, especially in such a way that the deflecting element can be inclined only up to a maximum angle.

In general, without restriction to the examples shown, the recesses 90 and the lands 92, 94, but especially the material-weakening structure, may have further embodiments that are not shown. For instance, the deflecting element may generally be provided with a kink region in that a local, single-sided or double sided thinning (“local slimming”), for example by an etching process. In principle, a thinning is indeed also envisaged in the embodiments of FIGS. 11 to 13, but here with more complex structuring.

For example, the lands may also take the form of rectangular or square projections. The recesses 90 may additionally be configured in different shapes; for example, the recesses 90 may be of trapezoidal or nearly triangular shape, or the shape of a rounded depression. If, however, the aim should be a continuous surface of the wafer 2, it is possible for this purpose for the recesses 90 to be filled with organic materials, for example with plastics, rubber or adhesives. Depending on the application, it may also be advisable to leave some of the recesses 90 open. It is thus possible to provide a wafer 2 in which at least a portion or some of the number of recesses 90 are filled with organic materials.

In one development of the embodiment with the recesses 90 filled with organic materials, the organic material is chosen and adapted such that the reaction force changes by a highest maximum magnitude because of a deflection of the deflecting element 14. This change is measured relative to an embodiment with open recesses, i.e. without organic material-filled recesses 90.

It is preferably also possible to produce an encapsulated optoelectronic component 1 using a base element. The base element preferably comprises a carrier 3 and a spacer 4 disposed thereon with openings 20 that define the cavities into which optoelectronic components 9 can be inserted. These cavities 6 preferably have a height corresponding to the thickness of the spacer 4. This may be specified, for example, with a value greater than 0.5 mm, preferably greater than 0.7 mm, and/or less than 3.0 mm, preferably less than 2.6 mm, more preferably less than 1.5 mm. Particular preference is given to a thickness between 0.5 mm and 1 mm. The thickness of the carrier may preferably be specified with a value between 0.5 mm-1 mm. In one embodiment, the carrier and/or the spacer takes the form of a wafer.

As an alternative to a combination of carrier 3 and spacer 4, the base element, especially in the form of a substrate or substrate wafer, in a further embodiment, may itself be made by upstream manufacturing processes as cavity 6. A similar construction is shown by way of example in FIG. 2. In this case, the spacer wafer 4 may be dispensed with. But the aforementioned height values of the cavity 6 or of the cavities 6 may likewise be maintained.

In another embodiment, it is conceivable that the cavities 6 are defined both by recesses in the carrier 4 and by recesses in the spacer 4. In this case, the spacer 4 and the carrier 3 may be mounted one top of another in such a way that the respective recesses define a common cavity 6 or a common opening. In this way, the height of the cavities 6 or openings can be assured and, at the same time, the thickness of the spacer 4 can be reduced, which enables a more compact design overall.

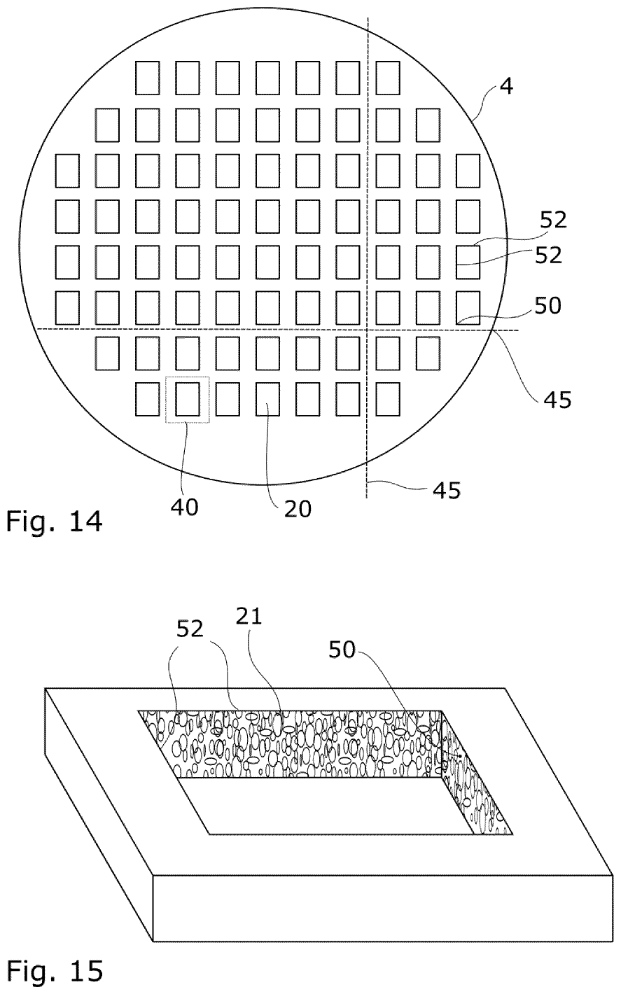

There follows a detailed description of the spacer. FIGS. 14 and 15 show examples of spacers 4, especially spacer wafers. The embodiment of FIG. 14 shows a round spacer 4. A round shape of the spacer 4 may be favorable, for example, for a wafer-level packaging process in which the spacer 4, prior to the separation, is bonded to other components of the encapsulated optoelectronic components 1, for example a wafer 2, by deflecting elements 14 or a carrier 3.

The spacer 4 serves in particular for production of spacers for the housing of optoelectronic components 9 by removal of sections 40 from the spacer 4. In general, for spacers 4, preference is given to using glasses having coefficients of expansion of less than 10·10⁻⁶ K⁻¹, preferably less than 8·10⁻⁶ K⁻¹, in order to keep thermomechanical stresses low especially in a wafer assembly with the standard materials for the purpose. The spacer 4 therefore preferably comprises or consists of a transparent glass sheet. This has a multitude of mutually separate openings 20 in a grid distribution. If sections 4 of the spacer 4 are separated off along dividing lines 45 that run between the openings 20, singularized spacers are obtained, each of which has an opening 20 with a circumferential closed edge. However, the singularization may also be effected only after bonding of the components of the encapsulated optoelectronic component 1.

In yet another embodiment, the spacer 4 has a very low variation in thickness (TTV =Total Thickness Variation). The variation in thickness of the spacer 4 in this embodiment is less than 10 μm, preferably 5 μm, preferably less than 2 μm, more preferably less than 1 μm. This low TTV value is favorable and necessary, among other reasons, in order to be able to bond the different wafers to one another over the whole area in the case of assembly of the encapsulated optoelectronic components 1 at the wafer level. A low TTV value is also favorable in order to be able to very accurately position an optical component that has been applied atop the spacer 4 or bonded to the spacer 4. A low TTV is equally important in order to achieve maximum compliance of spacing, especially in optical systems.

In a particularly preferred embodiment of the spacer 4, side walls 50 of the openings 20 each have at least one flat section 52, preferably at least 2 flat sections 52, that are especially arranged transverse to one another. Light can enter through these flat sections 52 without the side wall 50 acting as a lens or cylinder lens or deforming the spatial intensity profile of the light in some other way.

In general, without restriction to the specific examples described, the side walls 50 of the openings 20 may also have four flat sections 52. It is possible here in particular for two flat sections 52 each to lie opposite one another. This feature is satisfied particularly when the openings 20 have a basic rectangular or square shape. But the feature is also satisfied when the corners of rectangular or square openings 20 have been rounded off.

FIG. 15 shows a perspective view of a detail of the spacer 4 with an opening 20. The openings 20 have side walls 50, where at least one of these side walls 50, but in particular all side walls, have microstructuring 21 with a roughness. This roughness has an average roughness value Ra of less than 3 μm, especially less than 2 μm, more preferably less than 0.5 μm, at a measurement distance of 500 μm. The microstructuring 21 is symbolized in FIG. 15 by an irregular arrangement of different-sized circles and ellipses. The outer wall of the spacer 4, or else of the wafer 2, may likewise have such microstructuring 21. Both the wafer 2 and the spacer 4 may be structured by means of an ultrashort pulse laser, for example as shown in FIG. 3, and optionally also by means of a subsequent etching method.

In particular, it is possible here to adjust the roughnesses of the side walls 50 of the openings 20 via a suitable choice of the laser parameters and etching parameters. It is advantageously possible to influence a side wall 50 to be created around the envisaged openings 20 by means of a skillful choice of the number of individual pulses within a pulse packet, and in particular to establish a structure of the side walls 50 in a controlled manner. Since the overall power of a laser pulse in a pulse packet or in a burst is distributed between several individual pulses, each pulse has lower energy compared to an individual laser pulse. The result is that, with a higher number of individual pulses, the energy of each single individual pulse decreases. In particular, the total energy of the pulse group may be distributed uniformly between the individual pulses.

Moreover, in the case of operation of the ultrashort pulse laser in burst mode, the repetition rate may be the repetition rate of the release of bursts. In addition, the individual pulses arrive at the lateral face 2a, 2b of the wafer or at the damage site over a period of time, such that each individual pulse changes the previously created state of the side walls 50. In this way, it is possible to structure and alter the side walls 50 in a controlled manner by choice of the number of individual pulses in a burst.

The typical power of the laser source is particularly favorably within a range from 20 to 300 watts. In order to achieve the damage sites/channels, in an advantageous development of the invention, a pulse energy of the pulses and/or of pulse packets of more than 400 microjoules is used, further advantageously a total energy of more than 500 microjoules. A suitable pulse duration of a laser pulse is in a region of less than 100 picoseconds, preferably less than 20 picoseconds.

However, it may also be the case that a pulse duration is chosen that is less than 15 ps, preferably less than 10 ps, preferably less than 5 ps. Preference is even given to using a pulse duration of 1 ps in order to create a smooth side wall 50, especially with a low roughness or a low average roughness value. It is possible here to increase roughness with increasing pulse duration. One reason for this may be the thermal behavior of the glass, since the glass in the case of a longer pulse duration is consequently exposed for longer to the laser energy, and hence also to the resultant heat from the laser beam, as a result of which less thermally stable glass in particular is damaged, for example as a result of expansion. Consequently, the glass of the glass element may be damaged in a specific manner by precise choice of the pulse duration, and hence ideally also a roughness of the side walls 50. The burst frequency may be in the range of 15 MHz to 90 MHz, preferably in the range of 20 MHz to 85 MHZ, and is, for example, 50 MHz.

It is also advantageous when the damage sites 103 are arranged at a distance from one another, and this distance is less than 20 μm, preferably less than 15 μm, preferably less than 10 μm, and/or greater than 1 μm, preferably greater than 2 μm, preferably greater than 3 μm. However, the distance between the damage sites 103 may also be greater than 5 μm and/or less than 100 μm, preferably less than 50 μm, preferably less than 15 μm. Irrespective of the diameter of the damage site 103, the distance between adjacent damage sites 103 may also be referred to as pitch, i.e., for example, an interval between the laser pulses that are emitted at the same time or in particular successively at a distance from one another. This distance/interval is measured from the middle to the middle of the damage sites 103, or else from the center of a pulse to the center of an adjacently emitted pulse. With the choice of distance between the damage sites 103, it is possible to influence roughness in that the sections between the channels need not be deliberately processed by the laser, and are subjected solely to a subsequent etching process. The sections between the channels, or the distance between the damage sites 103, preferably has dimensions that preferably correspond to the thickness of the spacer 4 or wafer 2.

In order to be able to optimize the structure or roughness of the side walls 50, at least one of the following correlations can be established:
burst×pulse duration=constant
pitch/material removed=constant

With regard to these relationships, it becomes clear that the laser parameters, and especially the pitch and burst, for example the number of individual pulses in a pulse packet, have a considerable influence on the roughness of the side walls 50.

As described by the example of production of the wafer 2, the damage sites 103 may be arranged along closed paths that surround the openings 20 to be created. For creation of the openings 20 of the spacer 4, it is therefore possible, in a further step, to widen the damage sites 103, as by an additional etching process in the example of wafer production, to such an extent that continuous cuts are created and the openings 20 within the closed paths can be opened up in this way.

The etch medium may be gaseous, but preference is given to an etch solution. The etching, in one embodiment, is therefore conducted by wet chemical means. This is favorable in order to remove glass constituents from the inner surfaces of the damage sites during the etching. In this way, the side walls 50, in accordance with the requirements, may be endowed/created with low roughness and in particular advantageous cup-shaped depressions. Such depressions are, for example, part of the microstructuring 21 and are shown as circles and ellipses of different size in FIG. 15.

Preferably, the whole spacer 4 and/or wafer 2 is exposed to this etch medium, such that, for example, a multitude of openings can be created simultaneously, or in one manufacturing step. For this purpose, it is possible to use either acidic or alkaline solutions. Suitable acidic etch media are in particular HF, HCl, H₂SO₄, ammonium bifluoride, HNO₃ solutions or mixtures of these acids. For basic etch media, for example, KOH or NaOH solutions are useful. Ideally, the etch medium to be used may be selected according to the glass of the glass element that is to be etched.

In one embodiment, the removal rate for adjustment of the microstructuring can be adjusted via the choice of a combination of glass composition or material composition of the spacer 4 and/or of the wafer 2, and the composition of the etch medium. In the case, for example, of a glass with a high calcium content, for example, preference is given to choosing an acidic etch medium, whereas, in the case of a glass with a lower calcium content, preference is given to using a basic etch medium. On the other hand, the removal rate, i.e. the etch rate, is very much higher in the case of an acidic etch medium and a glass with a high silica content than in the case of a basic etch medium, but the acidic etch medium is also neutralized very much faster, by the substances already dissolved, and hence the etch medium is used up, or saturated with glass. Accordingly, depending on the material composition of the spacer 4 and/or the wafer 2, an acidic etch medium may be chosen for establishment of a fast rate of material removal, or a basic, especially alkaline, etch medium for establishment of a slow rate of material removal.

In order to be able to better control the removal of material, however, a slower rate of material removal or a basic etch medium is preferred. As a result, it is possible to achieve a material removal rate of less than 5 μm/h, preferably less than 4 μm/h, preferably less than 3 μm/h, and/or greater than 0.3 μm/h, preferably greater than 0.5 μm/h, preferably greater than 1 μm/h, preferably greater than 1.5 μm/h, and in particular between 2 μm/h and 2.5 μm/h. Such a material removal rate advantageously allows sufficient time even during the etching operation to influence the etch medium, or the etching operation.

Further variable etching parameters are, for example, the supply of additives or temperature. For example, preference is given to a temperature between 40° C. and 150° C. This temperature creates sufficient mobility of the ions to be dissolved or constituents of the material of the spacer 4 and/or wafer 2.

A further factor is time. For example, it is generally possible to achieve higher material removal when the spacer 4 and/or wafer 2 is exposed to the etch medium for several hours, especially for longer than 30 hours, or only 10 hours for example. On the other hand, it is possible to limit material removal by exposing the glass element to the etch medium for less than 30 hours, for example only 10 hours. In general, the material removal rate is defined by temperature, the composition of the etch medium, the duration of etching, and the composition of the material of the spacer 4 and/or wafer 2. By establishment of a higher material removal rate, especially above 2 μm/h, it is possible, for example, to achieve an average roughness value (Ra) below 15 nm.

It may additionally be the case that defined regions of a lateral face of the wafer 2 or of the spacer 4 are to be shielded with respect to the etch medium, for example particular regions such as the foldover region 13 of the wafer 2. This can be implemented, for example, by the use of specific holders by which the wafer 2 or the spacer 4 is held in the volume of the etch medium. In addition, specific form elements are conceivable, which are disposed on the wafer 2 or the spacer 4 before they are exposed to the etch medium. It is also possible to apply a protective layer, for example a polymer layer, in selected regions of the wafer 2 or the spacer 4 before they are exposed to the etch medium. In this way, it is possible in particular to achieve an average roughness value (Ra) of these regions of less than 40 nm, preferably less than 25 nm, and hence a particularly smooth surface.

Because of this method, the side walls of the openings 20 of the wafer 2 and/or the spacer 4 have cup-shaped depressions. The cup-shaped depressions ideally form a special microstructuring 21 of the side walls that brings several advantages. For instance, the rounded structures or cups are a particularly favorable form in order to degrade tensile stresses that occur at the edge surface down to the deepest points on the surface of the side wall, namely the deepest points of the cups. This effectively suppresses the growth of cracks at possible defects in the edge surface.

The side walls preferably have a proportion of their area with convex-shaped regions of less than 5%, preferably less than 2%. Ideally, an area proportion of concave-shaped regions, i.e. regions with cup-shaped depressions, is therefore greater than 95%, preferably greater than 98%, of the side wall surface area. What is meant here by concave is that a curvature runs in the direction of the wafer 2/spacer 4, and by concave that a curvature runs away from the wafer 2/spacer 4, i.e. in the direction of the openings 20. A depth of the cup-shaped depressions is typically less than 5 μm, ideally in the case of transverse dimensions of preferably between 5-20 μm.

It is further conceivable that it is possible via controlled adjustment of the rate of material removal to alter the depth and size or dimensions of the cups. For example, in the case of a higher rate of material removal, flatter and broader cups may be formed, such that the surface of the side walls may be made smoother.

For production of an encapsulated optoelectronic component 1, it is then possible to provide a multitude of optoelectronic components 9, a base element having cavities 6, the wafer 2 that has in particular been etched, and at least one cover element 5. Advantageously, the base element has a carrier 3 and a spacer 4 that forms the cavities 6. These constituents may then be arranged one on top of another. For this purpose, one or more optoelectronic component(s) 9 in each case is/are disposed in a cavity 6, and the wafer 2 is disposed between the cover element 5 and the spacer 4, especially such that an assembly of encapsulated optoelectronic components 9 is provided. At least one deflecting element 14 or all deflecting elements 14 here is/are tilted into a cavity 6. FIG. 16 shows, by way of example, such an assembly in cross section, where, for the sake of clarity, only a detail of a cavity 6 is shown with the components arranged therein and around it.

The optoelectronic components 9 are preferably disposed directly on the base element, the substrate or, more preferably, on the carrier 3. However, it is also conceivable that the optoelectronic components 9 are each disposed on a submount, which is disposed in turn on the base element, the substrate or, more preferably, on the carrier 3. In an alternative embodiment, the optoelectronic components 9 may also be disposed on the cover element 5. The cover element may generally have a thickness between 300 μm and 700 μm.

Each optoelectronic component 9 may also be supplied electrically, for example, via one or more electrical bushings in the base element, the substrate or the carrier 3. For example, at least one or more than one optoelectronic component 9 may be bonded or have been bonded to the bushings by bond wires. At least one or more than one optoelectronic component 9 may also take the form of an SMD unit. In this case, solder balls may be placed on the bushings. Many other designs do of course exist here. In a further possible design, for example, the carrier 3 may itself be part of the optoelectronic components 9, for instance when the carrier 11 is a semiconductor substrate in which the optoelectronic components 9 are formed. Preference is given, however, to a power supply of the optoelectronic components 9 via the carrier 3 or even capacitive energy supply.

In one embodiment, at least the cover element 5, the wafer 2 and/or the base element or the carrier 3 and the spacer 4 are provided with alignment marks in order to enable precise positioning of these elements with respect to one another as well. The alignment marks may, for example, be holes or markings. In a preferred embodiment, therefore, the cover element 5, the wafer 2 and/or the base element or the carrier 3 and the spacer 4 are combined to give a stack, and all elements of the stack are provided with alignment marks simultaneously, or in parallel. In a further embodiment, this is done at the start of the manufacturing process. In this way, especially at a later juncture, it is possible to position the openings 20 of the wafer 2 and of the spacer 4, for example, in such a way that a common cavity 6 in each case is formed by one opening 20 each in the wafer 2 and in the spacer 4. In addition, it is possible to ensure by precise positioning that one deflecting element 14 in each case can be tilted into one of these cavities 6.

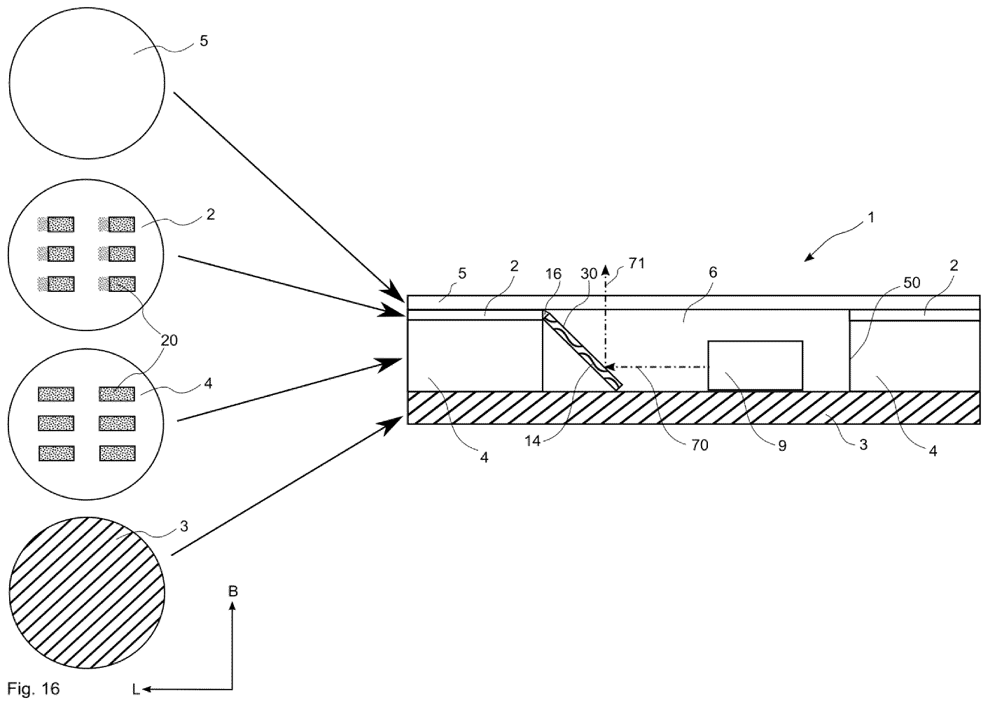

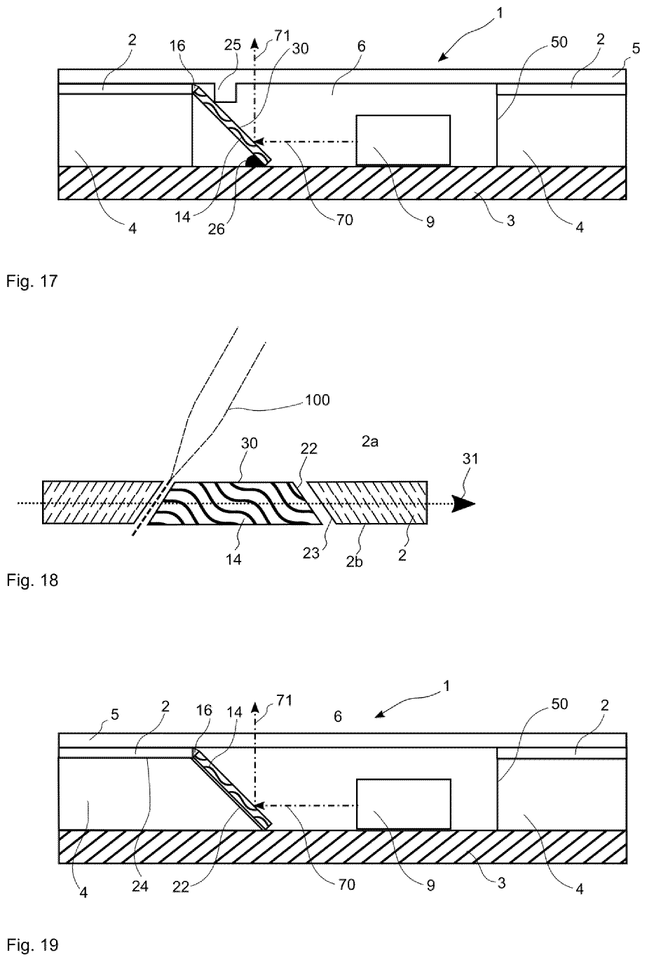

In one embodiment, the deflecting element 14 may be tilted into the cavity 6, for example, in the course of or during positioning or bonding of the components of the encapsulated optoelectronic component 1, for example in the direction of the base element, the substrate or carrier 3, or the cover element 5, or downward or upward. This can firstly be done automatically, especially with the aid of gravity or gravitational force, or secondly by means of forces supplied. Such forces may be exerted, for example, by a pressure element. Such a pressure element may be used before the cover element 5 is applied to the wafer 2. However, the pressure element may also be part of the cover element 5, for example in the form of a projection 60, which projects into the cavity 6 and hence in particular pushes the deflecting element 14 into the cavity 6. This case is shown by way of example in FIG. 17. The projection 25 is disposed here on the cover element such that the projection 25, during the placing of the cover element 5 on to the wafer 2, is pressed onto the optical surface 30 of the deflecting element 14 such that it folds into the cavity 6 as a result of the pressure. In other words, the deflecting element 14 is designed such that it folds over before or during mounting of the cover element 5, or can instead be tilted into the cavity 6. In this way, the deflecting element 14 advantageously need not be brought into a position envisaged for use subsequently, i.e. after mounting. In an alternative or additional embodiment, which is particularly preferred, the folded-over deflecting element 14 is secured on the carrier 3. For this purpose, for example, a securing element 26 may be provided, which fixes the deflecting element 14 to the carrier 3, for example on its opposite edge from the material-weakened structure 16. In a simple embodiment, the deflecting element may simply be bonded to the carrier 3. In this case, the security element 26 accordingly comprises a bond or generally an adhesive, especially in the form of an organic adhesive. Alternatively or additionally, fixing of the deflecting element 14 to the carrier 3 by its opposite edge from the material-weakened structure 16 is possible by laser bonding, glass soldering or metal soldering. In general, it is possible to use the same methods by which the elements of the wafer assembly are bonded.

In an advantageous embodiment, the deflecting element 14 has at least one oblique edge 22, the face of which is preferably at an angle between 100° and 170° to a lateral face 2a of the wafer 2, but especially to the optical surface 30 of the deflecting element 14. Such a case is shown in schematic form in FIG. 18. This oblique edge 22 preferably lies opposite a complementary internal face 23 of the wafer 2. The oblique edge 22 is advantageously also arranged transverse, especially at right angles, to a bending axis of the deflecting element 14, for example of the first axis 31. By means of an oblique edge 22 at the outer face of the deflecting element 14, canting of the deflecting element 14 at the wafer 2 can be effectively avoided during bending, tilting or folding.

In order to create such an oblique edge 22, it is advantageous when the incident energy of the laser beam 100 creates, at least in the region of some of the paths, filamentous damage sites 103 in the volume of the wafer 2, the lengths of which run at an angle between 80° and 10° to a lateral face 2a of the wafer 103, especially not at right angles to the lateral face 2a. In other words, the cuts are not created at right angles to the lateral faces 2a, 2b, but obliquely.

In a similar manner, it is also possible to create an oblique edge 22 in the spacer 4, as shown for example in FIG. 19. It may therefore be the case that the spacer 4 has at least one oblique edge 22, the face of which preferably runs at an angle between 100° and 170° to a contact face 24. The oblique edge 22 of the spacer 4 may serve to catch the deflecting element 14 when it folds over, or to limit the bending angle or angle of inclination of the deflecting element 14. In such a case, the oblique edge 22 of the spacer gives a maximum angle by which the deflecting element 14 can be moved. The deflecting element 14 may thus also lie on the spacer 4; in particular, the deflecting element 14 may lie on an oblique edge 22 of the spacer 4. In this case, it is also possible to provide a securing element 26 that connects the deflecting element 14 to the oblique edge 22.

It may further be the case that the cover element 5, the wafer 2 and the base element are joined permanently; for example, the individual elements may be bonded to one another by (adhesive) bonding, especially anodic bonding. The elements are preferably welded by means of an ultrashort pulse laser, wherein all elements are welded at different depths by variation of focusing and hence bonded to one another in one step. The laser focus may in each case be directed in particular here onto the contact surfaces of two components of the assembly or of the encapsulated component 1. Then the material in the laser focus is melted, and hence the contact surfaces are bonded to one another. Mention is made by way of example of the contact surface of the cover element 5 with the wafer and/or contact surface of the wafer 2 with the base element or substrate. However, the focus may also be directed on the contact surface of the carrier 3 with the spacer 4. In this way, all necessary contact surfaces, or components, may be bonded to one another in a fluid-tight, especially hermetically sealed, manner.

The ultrashort pulse laser welding process offers the advantage that varying the focusing allows working at different depths of the component stack, meaning that a (common) process of mounting the components and/or wafers used is sufficient to be able to achieve permanent sealing. Alternatively, methods used for permanent hermetic bonding of the components may include the conventional methods such as adhesive bonding, contact bonding, bonding or fusion by means of a glass frit.

A preferably last step for production of an encapsulated optoelectronic component 9 envisages singularization of the assembly of encapsulated optoelectronic components 9 along dividing lines 45 between the cavities 6 to give individual encapsulated optoelectronic components 9. These dividing lines 45 may run, for example, as shown in FIG. 14, especially such that the encapsulated optoelectronic components 1 are obtained by separating off sections 40 from the assembly. In this way, in a simplified manner, it is possible to manufacture a multitude of individual encapsulated optoelectronic components 1, especially such that it is possible to dispense with individual manufacture or subsequent processing of individual components.

The encapsulated optoelectronic component 1 is accordingly preferably produced or producible from an assembly of encapsulated components 1 and has a housing that surrounds, especially hermetically encloses, at least one optoelectronic component 9. The housing is preferably formed from a base element, especially a base element with a carrier 3 and at least one spacer 4. In particular, the spacer 4 has at least one opening 20 that defines a cavity 6 which is preferably formed by the side walls 50. The cavity 6 is bounded by the carrier 3 at a lower end and by a cover element 5 at a top end. The optoelectronic component 9 is accordingly disposed in the cavity 6, and especially between the side walls 50, preferably between the cover element 5 and the carrier 3.

The optoelectronic component 9 preferably comprises or is an edge-emitting diode, especially laser diode (EELD). The EELD, in one development, may emit in the blue VIS region. Such laser diodes typically emit wavelengths between about 400 nm and 500 nm. Particular preference is given, however, to diodes that emit at least one of the wavelengths 405 nm, 445 nm, 473 nm and/or 485 nm. In other executions, however, it is also possible to use other wavelengths, for example wavelengths between 500 and 800 nm or those from the infrared region, especially near and middle infrared region, or shorter wavelengths below 400 nm, for example from the ultraviolet region. Such EELs, for technological reasons, must be hermetically shielded from the environment, which is implemented by means of the housing. An important field of use may, for example, be laser lighting, where the blue laser light can be converted to different wavelengths and rendered diffuse with phosphor converters. The laser diode may accordingly work in the mW to W range, for example at 3 mW to 5 W. The dimensions of the laser diode may vary between 500 μm and 2000 μm in length and between 500 μm and 1000 μm in width, and preferably be about 100 μm, for example between 50 μm and 300 μm, in height. Accordingly, the cavity 6 has dimensions that are greater in terms of length, width and height than the dimensions of the optoelectronic component 9, such that this fits optimally into the cavity 6.

In one embodiment, the spacer 4 is secured on the carrier 3 on the side with the optoelectronic component 9, and a one-piece sheet element 8 with at least one tongue-shaped deflecting element 14 is preferably secured on the spacer 4. The sheet element 8 here originated from the wafer 2 in the course of singularization and hence comprises the same material as the wafer 2. The cover element 5 or a further sheet element 8 is preferably disposed on the sheet element 8, and then the cover element rests thereon. At least one sheet element 8 with at least one tongue-shaped deflecting element 14 is therefore provided between the spacer and the cover element.

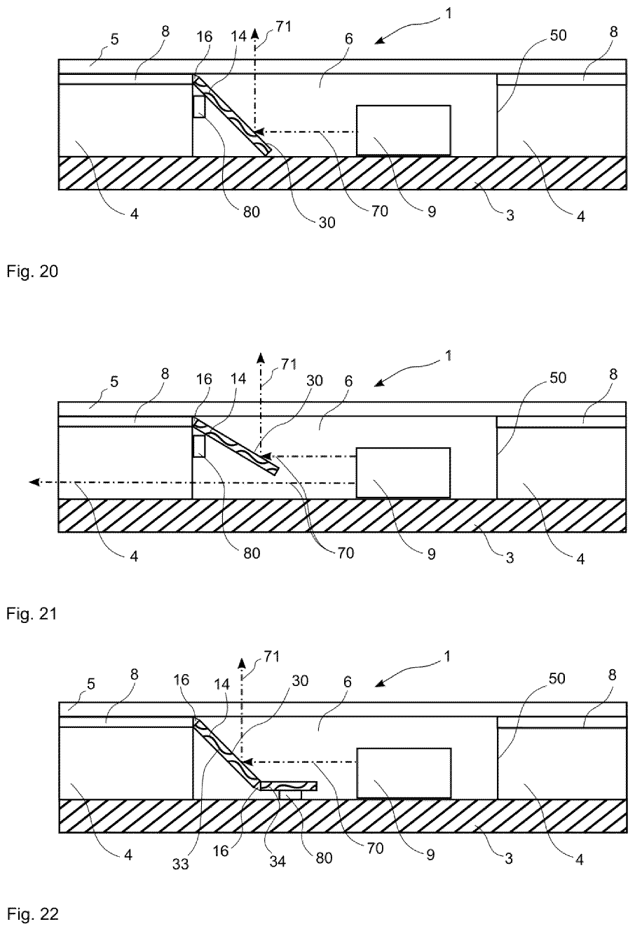

It is possible here in particular for light 70 which is emitted by the optoelectronic component 9, especially the laser diode, to cross the cavity 6. The light may then hit a side wall 50 opposite the optoelectronic component 9 and/or hit the deflecting element 14, which is arranged in the cavity 6 such that the deflecting element 14 can deflect the light 70 by at least one optical surface 30. One example of this is shown by FIG. 20. It is envisaged that the light 70 is deflected by the deflecting element 14, such that deflected light 71 runs in the direction of the cover element 5 and in particular exits from the encapsulated optoelectronic component 1 via the cover element 5.

In one embodiment, the cover element 5 may be used to introduce further optical elements into the beam path. For example, the surface of the cover element 5 may be structured with trenches in a laser ablation process. The trenches may then be filled with a further optically active material, in order, for example, to create a (phase) grating. It is thus possible to improve optical quality, and in particular to achieve sufficiently low roughness for avoidance of scatter. By means of a phase grating produced in such a way, it is possible to match the wavefront of the emitted (laser) light 70 and hence the waveform to the further use in the optical structure right at the start of the emission process. The structured surface may secondly also be smoothed by an acidic or alkaline etching process. Further forms of structuring are likewise possible, such as the introduction of convex-or concave-curved surfaces onto the cover element 5.

In a particular embodiment, it is also possible to apply to the cover element 5 liquid lenses known from the prior art, the geometric shape of which can preferably be adjusted in a variable manner by application of a field, in order to be able to flexibly adjust the beam from the EELD. For this purpose, at least one further spacer is then needed, which may especially be disposed between two cover elements 5. In this way, the liquid lenses between the two cover elements may be implemented.

In an advantageous embodiment, the deflecting element 14 has at least one of the following features:
the deflecting element 14 is reversibly foldable into the cavity 6,
the deflecting element 14 is tiltable or tippable such that the optical surface 30 of the deflecting element 14 can deflect electromagnetic rays, especially light 70, in the direction of the cover element 4 or of the optoelectronic component 9, where the optoelectronic component 9 receives or emits the electromagnetic rays laterally and hence the electromagnetic rays are incident obliquely on the optical surface 30, especially at an angle other than 90°,
the folded-over deflecting element 14 is secured on the carrier 3.

By virtue of the deflecting element 14 being foldable reversibly into the cavity 6, the deflecting element 14 may be adjusted precisely to an envisaged angle. In this way, it is also possible to emit the light 71 deflected by the deflecting element 14 at a particular angle. In general, the thickness of the spacer 4 and of the deflecting element 14, and the spatial extent thereof, determine the maximum angle of inclination of the deflecting element 14 and hence the range of spatial angles accessible to the laser beam. In FIG. 19, the maximum angle of inclination of the deflecting element 14 in the direction of spacer 4 is defined, for example, by the oblique edge 22 of the spacer 4 onto which the deflecting element 14 may be placed by way of example. In other designs, the thickness of the spacer 4, i.e. in particular the height of the side wall 50, is smaller than the length of the deflecting element 14. It is thus possible to ensure that the deflecting element 14 in the maximally inclined state not vertically but obliquely to the direction of propagation of the laser beam, for example the light beam 70 emitted by the diode.

In a further embodiment, the deflecting element 14 has a wedge angle. Given suitable surface characteristics, especially a suitable coating of the two surfaces of the wedge-angled deflecting element 14, it is possible to achieve the effect that some of the light 70 emitted by the EELD is reflected at the optical surface 30 of the deflecting element 14, but the remaining proportion is reflected at a second surface only after passing through the deflecting element 14, and hence two part-beams leave the housing at different angles, or else at equal angles in the case of a wedge angle of 0°.

In order to be able to render the optical properties of the deflecting element 14 flexible, therefore, at least one of the following features is provided:
at least the optical surface 30 of the deflecting element 14 takes the form of a mirror surface,
at least the optical surface 30 of the deflecting element 14 is structured and/or coated,
the coating comprises a dielectric material, a metal and/or a layer system composed of dielectric layers.

The stated options for configuration of the deflecting element 14 therefore also permit precise adjustment of the optical properties of the deflecting element 14 in relation to predetermined wavelengths and/or applications. The optical properties of the deflecting element 14 may therefore especially be designed in a wavelength-dependent manner, preferably such that, for example, the laser beam reflects a first wavelength 21 hitting the optical surface 30, and the beam of a second wavelength 22 is transmitted by the optical surface 30. This is advantageous, for example, when laser diodes capable of emitting second or third harmonics are used or if light from different sources/of different wavelengths were to be combined. Such a procedure is advantageous, for example, in projection and display technology.

It is also advantageous when the angle of the electromagnetic rays deflected by the deflecting element 14, or deflected light 71, is reversible, variable or controllable during the operation of the optoelectronic component 9 by means of at least one actuator 80. It is therefore also conceivable, or envisaged, that at least one actuator 80 is positioned with respect to the incidence side of the electromagnetic rays, i.e. behind the deflecting element 14, such that the position of the deflecting element 14 is variable by means of the actuator 80. This embodiment is shown, for example, in FIGS. 20 and 21, where the actuator may comprise at least one piezo element. This may, for example, be a piezo crystal or a piezo ceramic. Piezo elements are of particularly good suitability for such applications since their dimensions are sufficiently small and the movement or deflection thereof is precisely controllable.

In other words, in one embodiment, there is at least one actuator/piezo element 80 disposed in a propagation direction of the laser beam from the diode or optoelectronic component 9 and beyond the deflecting element 14. Depending on the geometric size and thickness of the deflecting element 14, one actuator/piezo element 80 may even be sufficient. In the case of relatively thick deflecting elements 14, for example exceeding 0.6 mm, one actuator 80 may be sufficient. In the case of thin deflecting elements 14, for example below 0.6 mm, two or more actuators/piezo elements 80 are necessary owing to low dimensional stability. In the case of very thin deflecting elements, or wafers 2 or sheet elements 8, the thickness of which is less than 200 μm, because of the general pliability of the wafer 2 or sheet element 8, the material-weakened structure 16 may even be dispensed with. In this case, the deflecting element 16 bends into the cavity automatically, i.e. in particular under its own weight. In that case, several actuators/piezo elements 80 are needed here, which can preferably then also function as support elements. In general, the deflecting element 14 may also be connected to the actuator by means of at least one securing element 26. In this case, the securing element 26 may include an elastic adhesive that especially permits an intended change in angle without detachment of the deflecting element 14 from the actuator 80.

By means of the actuator(s) 80, repeated movement/bending of the deflecting element 16 and reproducible final positioning thereof are assured. It is thus also possible to position the deflecting element 16, especially after mounting of the encapsulated optoelectronic component 1, at various tilt angles/bending angles and hence to adjust the exit position and angle of the laser beam in a statically or dynamically flexible manner. This is particularly advantageous in the later application in order, for example, to be able to compensate for manufacturing tolerances.

An actuator 80 beyond the folding element likewise enables the flexible establishment of at least two different beam pathways in that, for example, a further fixed deflecting mirror or a prism or a passage to a further deflecting element 16 is disposed beyond the deflecting element 16. In particular, cascading of the construction is thus possible, as shown schematically in FIG. 21, where part of the light beam 70 is deflected by the deflecting element 16 and a further part of the beam runs through in the direction of and especially through the side wall 50. The deflecting element 16 in this case is inclined in the direction of the side wall to such an extent that part of the light beam 70 emitted by the diode can pass between deflecting element 16 and the carrier 3. In this way, for example, several optical components can be connected in series.

In a further embodiment, beyond the deflecting element 16, on or after introduction of a hole in the spacer element 4, there is a further electrooptical component, for example a monitor diode, that receives and evaluates the portion of the light 70 that goes beyond the deflecting element 14 and provides a closed-loop or open-loop control signal for control of the electrooptical component 9.

In other embodiments, for example, the deflecting element 16 may be inclined in the direction of the side wall 50 to such an extent that the deflecting element 16 adjoins the carrier 3.

While a defined angle of inclination is implemented and maintained in the static positioning of the deflecting element 16, dynamic positioning, for example by means of at least one actuator 80, permits scanning of the laser beam across an angle range. The encapsulated optoelectronic component may then, for example, be used as a miniaturized scanner.

It is advantageous when each deflecting element 14 has at least one deflecting section 33 and one positioning section 34, which are separated from one another by a material-weakening structure 16, in such a way that the deflecting section 33 is tiltable or bendable about the first axis 31 and the positioning section 34 is bendable about a further axis arranged parallel to the first axis 31. It is possible here for at least one actuator 80 to be disposed beneath the positioning section 34, i.e. between the positioning section 34 and the base element or the carrier 3.

Such an embodiment is shown in FIG. 22. Accordingly, the actuator 80 is disposed between the positioning section 34 and the carrier 3, or in particular on the carrier 3 or the base element. In this configuration, the actuator 80 can be supplied with electrical power in a particularly simple manner, especially when the carrier or the base element are electrically conductive or have electrical conductor tracks or electrical bushings. By means of the actuator 80, the positioning section 34 can be moved upward, or in particular in the direction of the cover element 5. In this way, the deflecting section 33 connected to the positioning section 34 also moves with the optical surface 30, as a result of which the angle of inclination of the deflecting element 14 or, in fact, of the deflecting section 14 is altered.

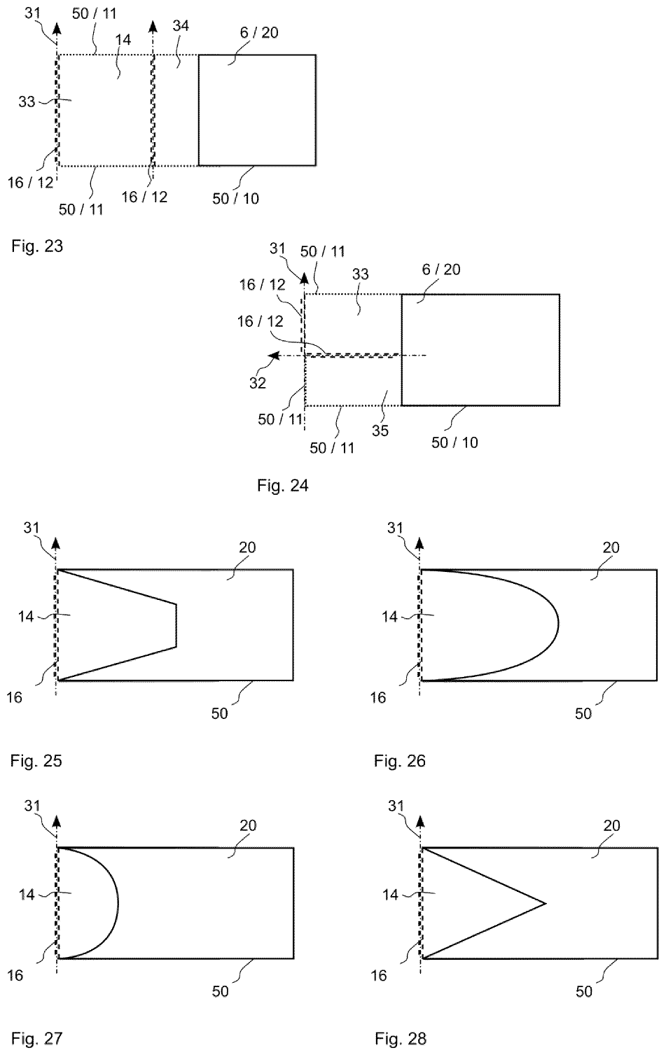

FIG. 23 shows the deflecting element 14 from FIG. 22 in top view and with adjoining cavity 6. What is shown is an illustration of the cuts that are employed in the creation of the deflecting element 14 and of the cavity 6 from the wafer 2 that in particular surrounds them. For a better overview, the respective elements shown are each given the reference numerals for the cuts, for example paths 10, 11, 12, and also the finally produced elements, for example the deflecting element 14. Accordingly, a closed path 10 is cut in order to create the opening 20 in the wafer 2 and the later cavity 6. Two open paths 11 are each cut adjoining the closed path 10 in order to increase the size of the opening 20, or the cavity 6, and to cut the deflecting element 14 free from the wafer 2 at these sites.

The two open paths 11 here are spaced apart from one another and preferably each arranged with an end point at a corner of the closed path 10. A connecting path 12 that indicates the material-weakened structure 16 is disposed between the two other corner points of the open paths 11. A further material-weakened structure 16 is disposed between the open paths 11 such that the deflecting section 33 is formed between two material-weakened structures 16, or connecting paths 12, that are especially parallel to one another. The two structures 16 thus form a bending axis, where a first axis 31 is preferably formed between the ends of the open paths 11. The positioning section 34 is thus connected to the deflecting section 33 via a material-weakened structure 16 and/or forms an outer element of the deflecting element 14.

In an advantageous embodiment, the or each deflecting element 14 may have at least two deflecting sections 33 that are separated from one another by a material-weakening structure 16 such that a first deflecting section 33 is tiltable or bendable about the first axis 31 and a second deflecting section 35 about a second axis 32, where the second axis 32 is arranged at an angle, especially transverse or at right angles to the first axis 31. Below each deflecting section 33, 35 may be disposed at least one actuator 80 here, such that the angle of the rays 71 deflected by the deflecting element 14 is flexibly adjustable statically or dynamically in at least two axes. Thus, positioning and alignment of the laser beam in two mutually independent directions and hence in the x-y plane is possible.

Such an embodiment is shown in top view, for example, in FIG. 24. As in FIG. 23, the corresponding cuts, or paths 10, 11, 12, are also shown in FIG. 24. The closed cut/path 10 again forms the opening 20/cavity 6. Adjoining these in each case are a corner point of an open cut/path 11, and in particular an end of a connecting path 12/material-weakening structure 16. The two deflecting sections 33, 35 are then the result of two connecting paths 12, or two elongated material-weakening structures 16, being in a transverse arrangement, especially at right angles to one another.

Alternatively, it is also possible to create a transversely curved or in particular perpendicularly kinked material-weakening structure 16/connecting path 12. The two deflecting sections 33, 35 are thus connected to one another at a material-weakening structure 16, where the second deflecting section 35 may be inclined relative to the first deflecting section 33 at the second axis 32. In particular, only the first deflecting section 33 is connected via a material-weakening structure 16 to the wafer 2, or the sheet element 8. The deflecting element 14 is preferably disposed in the cavity 6 such that the second deflecting section 35, which is preferably tiltable via the second axis 32, deflects the light 70 from the optoelectronic component 9. In other words, the second deflecting section 35 may be tilted indirectly via the first axis 31 and the second axis 32, which means that the light 30 can also be deflected in two mutually independent directions. Therefore, at least the second deflecting section 35 also has an optical surface 30 by which the light 30 can be deflected. However, it may also be the case that the two deflecting sections 33, 35 each have an optical surface.

Generally without restriction to the examples described, the material-weakened structure 16 may be in a flush arrangement, i.e. directly above a side wall 50 of the spacer 4, or offset with regard to the length of the cavity 6, especially in the direction of the optoelectronic component 9. In this way, the deflecting element 14 may be disposed closer to the optoelectronic component 9, or their mutual separation may be adjusted. In the case of a sufficiently thin or flexible sheet element 8 or wafer 2, it is also possible, especially in the embodiments of FIGS. 22 to 24, to dispense with the material-weakening structure 16, especially such that the deflecting section 33 and the positioning section 34 or the two deflecting sections 33 are connected directly to one another.

In the previous figures, the deflecting element 14 was shown in a rectangular or square shape. FIGS. 25 to 28 show various other geometric designs of the deflecting element 14. For example, FIG. 25 shows a trapezoidal deflecting element 14, FIG. 26 a semi-oval deflecting element 14, FIG. 27 a semicircular deflecting element 14, and FIG. 28 a triangular deflecting element 14. Other geometric shapes, such as polygons, or else mixed forms are likewise conceivable.

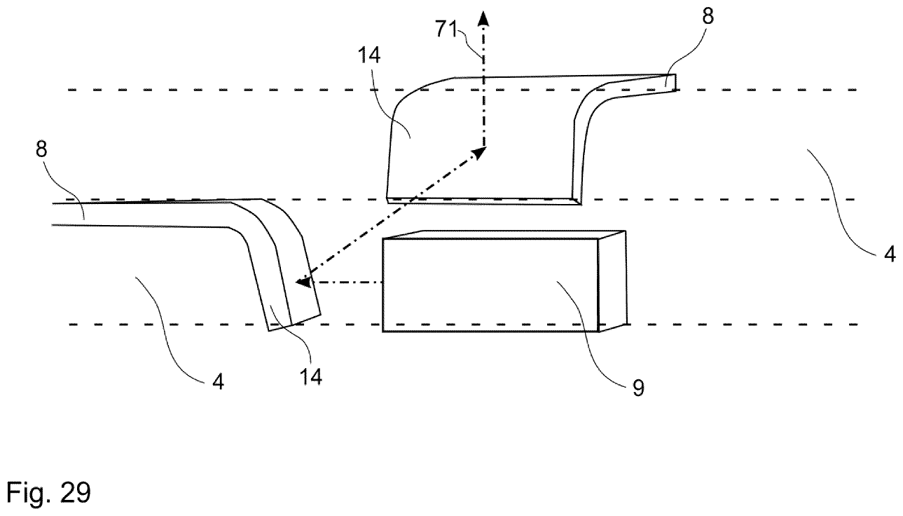

In a further embodiment, a second wafer 2, likewise structured in the form of one with deflecting elements 14, is integrated into the assembly, the deflecting elements 14 of which are rotated versus the alignment of the first deflecting elements 14, preferably at 90°, such that positioning and alignment of the laser beam is possible in two mutually independent directions and hence in the x-y plane. This variant can give rise to a design of an encapsulated optoelectronic component 1 as shown in FIG. 29. A spacer 4 is disposed here between the carrier 3 and a sheet element 8, and a further spacer 4 between two sheet elements 8. Thus, one sheet element 8 is positioned higher than the other sheet element 8. One deflecting element 14 is disposed on each sheet element 8, such that one deflecting element 14 is positioned higher than the other deflecting element 14.

The optoelectronic component 9 in this case is preferably positioned such that the direction of emission of the light is not at right angles to the first axis but at an angle, preferably an angle between 5° and 70°, preferably between 20° and 55°, more preferably at an angle between 40° and 50°. The result of this is that the light can be deflected at each deflecting element 14, in each case at an angle between 40° and 50° for example. In particular, the first axes or bending axes of the two deflecting elements 14 are arranged at an angle to one another of between 80° and 100°, especially 90°. Other combinations of angles are alternatively conceivable and are derivable by the person skilled in the art in a simple manner.

In the embodiments so far, the foldover element remains connected to the surrounding wafer, or glass element. But there is also a conceivable embodiment in which the deflecting element 14 is separated from the wafer 2 by fracture. In this case, rather than the bent material-weakening structure 16 as shown in FIGS. 16, 17, 19 to 22, there are respectively complementary fracture edges on the wafer and deflecting element 14, which are at a corresponding angle to one another by virtue of the folding-over of the foldover element 14. Therefore, in an alternative embodiment of the invention, an assembly of encapsulated optoelectronic components 1 is provided, which forms a housing having at least one base element and one cover element 5, where a multitude of optoelectronic components 9 is disposed in each cavity 6 of the housing which is formed by the base element and is covered on a top side by the cover element 5, such that the optoelectronic components 9 are disposed between the cover element 5 and the base element, and the base element forms side walls 50 that each laterally surround a cavity 6, where the base element especially comprises a substrate having recesses that define the cavities 6 and/or a carrier 3 and a spacer 4 disposed thereon and having openings 20 that define the cavities 6, where a one-piece structured wafer 2 is disposed between the cover element 5 and the base element, such that a tongue-shaped deflecting element 14 having at least one optical surface 30 is disposed in each cavity 6, with which electromagnetic radiation which is emitted or received by the optoelectronic components 9 can be deflected, where the deflecting element is in an inclined arrangement with respect to the one-piece structured wafer 2, and where the deflecting element and the one-piece structured wafer 2 (as a result of separation by fracture) have complementary, mutually inclined fracture surfaces corresponding to the angle of the deflecting element relative to the one-piece structured wafer 2. Accordingly, it is then possible by separation to obtain singularized encapsulated optoelectronic components 1 having a housing and at least one optoelectronic component 9 disposed in a cavity 6 which is formed by a base element and is covered on a top side by a cover element 5, such that the optoelectronic component 9 is disposed between the cover element 5 and the base element, and the base element forms side walls 50 that laterally enclose the cavity 6, where the base element comprises a substrate having at least one recess 90 that defines the cavity 6 and/or a carrier 3 and a spacer 4 which is disposed thereon and has at least one opening 20 that defines the cavity, where there is disposed, between the cover element 5 and the base element, a one-piece sheet element, wherein there is disposed, in the cavity 6, a deflecting element 14 which has at least one optical surface (30) and is in an inclined position relative to the one-piece sheet element and has been separated from the one-piece sheet element, with which electromagnetic radiation which is emitted or received by the optoelectronic component (9) is deflectable, where the deflecting element 14 and the one-piece sheet element (via the separation by fracture) have complementary, mutually inclined fracture surfaces corresponding to the angle of the deflecting element relative to the one-piece sheet element.

It will be clear to the person skilled in the art that the embodiments described above should be considered to be illustrative and that the invention is not limited to these, but can be varied in a variety of ways without leaving the scope of protection of the claims. Moreover, it will be apparent that the features, regardless of whether they are disclosed in the description, the claims, the figures or in some other way, also individually define essential constituents of the invention, even if they are described together with other features. In all figures, identical reference numerals represent identical articles, and so descriptions of articles that may be mentioned only in one or in any case not with regard to all figures can also be applied to those figures with regard to which the article is not explicitly described in the description.

### LIST OF REFERENCE NUMERALS

| | |
|---|---|
| 1 | Encapsulated optoelectronic component |
| 2 | Wafer |
| 2a | Lateral face |
| 2b | Lateral face |
| 3 | Carrier |
| 4 | Spacer |
| 5 | Cover element |
| 6 | Cavities |
| 7 | Edge of the deflecting element |
| 8 | Sheet element |
| 9 | Optoelectronic components |
| 10 | Closed paths |
| 11 | Open paths |
| 12 | Connecting paths |
| 13 | Foldover region |
| 14 | Deflecting element |
| 15 | Second section |
| 16 | Material-weakened structure |
| 17 | Maxima of the width of the recesses |
| 18 | Minima of the width of the recesses |
| 19a | Minima of the lands |
| 19b | Maxima of the lands |
| 20 | Openings |
| 21 | Microstructuring |
| 22 | Oblique edge |
| 23 | Complementary inner surface |
| 24 | Contact surface |
| 25 | Projection |
| 26 | Securing element for 14 |
| 30 | Optical surface |
| 31 | First axis |
| 32 | Second axis |
| 33 | First deflecting section |
| 34 | Positioning section |
| 35 | Second deflecting section |
| 40 | Sections |
| 45 | Dividing lines |
| 50 | Side walls |
| 52 | Flat section |
| 60 | Projection |
| 70 | Light |
| 71 | Deflected light |
| 80 | Actuator |
| 90 | Recesses |
| 91 | Rows of recesses |
| 92 | First lands |
| 94 | Second lands |
| 95 | Boundary lines |
| 96 | Linear segment |
| 100 | Laser beam |
| 101 | Ultrashort pulse laser |
| 102 | Focusing optics |
| 103 | Filamentous damage |
| 104 | Subareas |
| 150 | Light beam |
| 200 | Prior art design |
| 201 | Ceramic substrate |
| 202 | Submount |
| 203 | Laser diode chip |
| 204 | Window |
| 205 | Cap |
| 206 | Adhesive |
| 207 | Mirror prism |
| 300 | Etch medium |
| B | Transverse direction |
| L | Longitudinal direction |
| D | Thickness of the wafer |

1-19. (canceled)

20. A one-piece structured wafer for production of an assembly of encapsulated optoelectronic components with deflecting elements for deflection of electromagnetic rays, wherein the wafer is in sheet form and extends in a longitudinal direction and a transverse direction and is a sheet having two opposite lateral faces, and has a multitude of openings arranged in a grid distribution and separated from one another in the longitudinal direction and the transverse direction, wherein at least one tongue-shaped foldover region is defined in a region of each of the openings, wherein a tongue-shaped deflecting element with at least one optical surface can be formed in each case by folding over the foldover region and is permanently reversibly deformable as part of the one-piece structured wafer in such a way that each deflecting element can be repeatedly inclined or bent about at least one first axis.

21. The structured wafer of claim 20, wherein the at least one optical surface of is in planar form.

22. The structured wafer of claim 20, wherein at least one of the following is satisfied:
each deflecting element is connected to the wafer by a section having a material-weakening structure, such that smaller deformation forces are required for bending of a wafer material of the wafer in this section than in an unstructured section; or
each deflecting element is connected to the wafer by at least one severable subregion, such that the deflecting element remains connected to the wafer after the at least one subregion has been severed solely via a material-weakening structure.

23. The structured wafer of claim 22, wherein at least one of the following is satisfied:
the material-weakening structure has recesses that run partly through the wafer material across a thickness of the wafer such that only one lateral face is broken through by the recesses;
the material-weakening structure has recesses that run completely through the wafer material along the thickness of the wafer such that two opposite lateral faces are broken through by the recesses;
the material-weakening structure has recesses that are disposed alongside one another such that regions between which the material-weakening structure is disposed are connected to one another by lands;
the recesses are elongated;
the recesses are arranged in rows along an axis of inclination or bending; or
the recesses arranged in rows are arranged offset from one another.

24. The structured wafer of claim 20, wherein each deflecting element comprises at least two deflecting sections that are separated from one another by a material-weakening structure such that a first deflecting section is tiltable or bendable about the at least one first axis and a second deflecting section about a second axis, wherein the second axis is arranged at an angle transverse or at right angles to the at least one first axis.

25. The structured wafer of claim 20, wherein each deflecting element has at least one deflecting section and one positioning section that are separated from one another by a material-weakening structure in such a way that the at least one deflecting section is tiltable or bendable about the at least one first axis and the positioning section is bendable about a further axis arranged parallel to the at least one first axis.

26. An assembly of encapsulated optoelectronic components, comprising:
a housing with at least one base element and a cover element, wherein a multitude of optoelectronic components respectively is disposed in one cavity of the housing which is formed by the at least one base element and is covered on a top side by the cover element such that the optoelectronic components are disposed between the cover element and the at least one base element, and the at least one base element forms side walls that each laterally enclose a cavity, wherein the at least one base element comprises a substrate with recesses that define the cavities and/or define a carrier and a spacer disposed thereon and having openings that define the cavities; and
a one-piece structured wafer with tongue-shaped deflecting elements disposed between the cover element and the at least one base element such that a tongue-shaped deflecting element having at least one optical surface which is bent or repeatedly tiltable or bendable about at least one first axis is disposed in each cavity, with which electromagnetic radiation which is emitted or received by the optoelectronic components is deflectable.

27. The assembly of claim 26, wherein at least one of the following is satisfied:
the wafer has a thickness in a range of 0.03 mm to 1.3 mm;
the spacer has a thickness in the range of 0.3 mm to 3.0 mm;
the carrier has a thickness in the range of 0.3 mm to 3.0 mm; or the cover element has a thickness in the range of 0.1 mm to 2.0 mm.

28. The assembly of claim 26, wherein at least one of the following is satisfied:
the wafer comprises or consists of glass, glass-ceramic, ceramic, metal, plastic, or a mixture of these materials;
the carrier or the substrate comprises or consists of glass, glass-ceramic and/or ceramic;
the at least one base element or the spacer comprises or consists of glass, glass-ceramic and/or ceramic;
the cover element comprises or consists of glass transparent to electromagnetic rays; or
the cover element comprises or consists of tempered and/or toughened glass.

29. An encapsulated optoelectronic component producible from an assembly, comprising:
a housing and at least one optoelectronic component disposed in a cavity which is formed by a base element and is covered on a top side by a cover element such that the at least one optoelectronic component is disposed between the cover element and the base element and the base element forms side walls that laterally enclose the cavity, wherein the base element comprises a substrate having at least one recess that defines the cavity and/or a carrier and a spacer disposed thereon and having at least one opening that defines the cavity; and
a one-piece sheet element having at least one bent tongue-shaped deflecting element disposed between the cover element and the base element in such a way that there is disposed, in the cavity, the at least one deflecting element with at least one optical surface by which electromagnetic radiation which is emitted or received by the at least one optoelectronic component is deflectable.

30. The encapsulated optoelectronic component of claim 29, wherein at least one of the following is satisfied:
at least the at least one optical surface takes the form of a mirror surface;
at least the at least one optical surface is structured and/or coated with a coating;
the coating comprises a dielectric material, a metal and/or a layer system composed of dielectric layers.

31. The encapsulated optoelectronic component of claim 29, wherein at least one of the following is satisfied:
the at least one deflecting element is reversibly foldable into the cavity;
the at least one deflecting element is tiltable or tippable such that the at least one optical surface can deflect electromagnetic rays in a direction of the cover element or of the at least one optoelectronic component, where the at least one optoelectronic component receives or emits the electromagnetic rays laterally and hence the electromagnetic rays are incident obliquely on the at least one optical surface;
the folded-over at least one deflecting element is secured on the carrier; or
the at least one deflecting element is deformed and/or deformable such that the at least one deflecting element has a concave or convex shape.

32. The encapsulated optoelectronic component of claim 29, wherein an angle of electromagnetic rays deflected by the at least one deflecting element is reversibly variable or controllable by means of at least one actuator during operation of the at least one optoelectronic component.

33. The encapsulated optoelectronic component of claim 32, wherein the at least one actuator is positioned opposite a side of incidence of the electromagnetic rays such that the at least one deflecting element is variable in terms of its position by the at least one actuator.

34. The encapsulated optoelectronic component of claim 29, wherein at least one of the following is satisfied:
the at least one deflecting element has at least two deflecting sections that are separated from one another by a material-weakening structure such that a first deflecting section is tiltable or bendable about a first axis and a second deflecting section about a second axis, wherein the second axis is arranged at an angle transverse or at right angles to the first axis, wherein at least one actuator is disposed beneath each deflecting section such that an angle of rays deflected by the at least one deflecting element is flexibly adjustable statically or dynamically in at least two axes; or
each deflecting element has at least one deflecting section and a positioning section that are separated from one another by a material-weakening structure such that the at least one deflecting section is tiltable or bendable about the first axis and the positioning section about a further axis arranged parallel to the first axis, wherein at least one actuator is disposed beneath the positioning section between the positioning section and the base element.

35. A method of producing an encapsulated optoelectronic component, comprising:
creating cuts in at least one lateral face of a sheetlike wafer, wherein the cuts are created in the wafer along several defined and mutually spaced-apart closed paths and cuts are created in the wafer along several defined and mutually spaced-apart connecting paths and wherein the cuts of the closed paths run through the wafer, from one lateral face to an opposite lateral face, and the cuts of the closed paths create a material-weakened structure such that a sector is generated adjoining each connecting path that forms a tongue-shaped foldover region that remains at least indirectly connected to the wafer;
providing a multitude of optoelectronic components, a base element having cavities, the wafer, and at least one cover element;
disposing one optoelectronic component in each cavity and disposing the wafer between the cover element and the base element such that an assembly of encapsulated optoelectronic components is produced;
tilting at least one foldover region such that at least one deflecting element or all deflecting elements is/are tilted into a cavity; and
singularizing the assembly of encapsulated optoelectronic components along dividing lines between the cavities to give individual encapsulated optoelectronic components.

36. The method of claim 35, wherein at least the at least one cover element, the wafer and/or the base element or a carrier and a spacer are provided with alignment marks in order to enable precise positioning of these elements.

37. The method of claim 35, wherein the at least one cover element, the wafer and the base element are welded by means of an ultrashort-pulse laser, wherein all elements are welded at different depths by varying the focusing and hence bonded to one another in one operating step.

38. The method of claim 37, wherein incident energy from a laser beam of the laser in a region of at least some of the paths creates filamentous damage in a volume of the wafer, lengths of which run at an angle between 80° and 10° relative to a lateral face of the wafer.
